(19) United States
(12) Patent Application Publication
(10) Pub. No.: US 2008/0224214 A1
(43) Pub. Date: Sep. 18, 2008

(54) SEMICONDUCTOR DEVICE AND FABRICATION METHOD

(75) Inventor: Hong-fei LU, Matsumoto City (JP)

Correspondence Address: ROSSI, KIMMS & McDOWELL LLP., P.O. BOX 826, ASHBURN, VA, 20146-0826, US

(73) Assignee: FUJI ELECTRIC HOLDINGS CO., LTD., Kawasaki (JP)

(21) Appl. No.: 12/032,089

(22) Filed: Feb. 15, 2008

(30) Foreign Application Priority Data
Feb. 15, 2007 (JP) 2007-034537

(51) Int. Cl. H01L 29/786; H01L 21/336

(52) U.S. Cl. 257/347; 438/151; 257/E29.255; 257/E21.409

(57) ABSTRACT

The present invention provides an SOI device which has high breakdown voltage, wide stable operation range, good thermal dissipation, and high effective conductance and good frequency characteristics, and a method for fabricating the device. In a semiconductor device, a BOX region is formed on a part of a surface layer of a p substrate. The BOX region is formed around a point where a vertical line is dropped from the center of the gate structure portion, and isolates a drain region and an extended drain region from the p⁻ substrate. The thickness of the drain region is in a 150 nm to 300 nm range, and the thickness of the BOX region is 150 nm or more.

### CROSS-REFERENCE TO RELATED APPLICATION

This application claims priority from Japanese Patent Application No: 2007-034537 filed on Feb. 15, 2007, the content of which is incorporated herein by reference.

### BACKGROUND

The present invention relates to a semiconductor device, and more particularly to a semiconductor device which partially has an SOI (Silicon-On-Insulator) structure.

High-speed devices fabricated using a thin film SOI (Silicon-On-Insulator) substrate have been known. A device fabricated using a thin film SOI substrate (hereafter called “thin film SOI device”) can simplify element isolation, and decrease the parasitic capacitance of the device, compared with a device fabricated using a silicon bulk substrate (hereafter called “silicon bulk device”). Moreover the breakdown voltage can be increased by applying RESURF technology, so a thin film SOI device is also suitable for a power amplifier in a radio station in the 2 GHz band, and a high-speed device of which the breakdown voltage is a 15V class.

An example of a thin film SOI device having a conventional structure will now be described. In the present description and accompanying drawings, a semiconductor with an n or p indicates that an electron or a hole is a carrier respectively. “+” or “−” attached to an n or p, such as n⁺ and n⁻, indicates that the impurity density is relatively higher or lower than a semiconductor without these signs respectively.

FIG. 53 to FIG. 57 are diagrams depicting an example of a configuration of a thin film SOI device having a conventional structure. A semiconductor device 1000 shown in FIG. 53 is one disclosed in Japanese Patent Application Laid-Open No. 2001-244476. In the semiconductor device 1000 shown in FIG. 53, a buried oxide (BOX) region 1002 is formed on a part of a surface layer of a p⁻ region 1001 having high resistivity, which is formed on a surface layer of a p⁺ substrate 1016 having low resistivity.

A p body region 1005 is formed so as to contact a part of the surface of the BOX region 1002. The resistivity of the p body region 1005 is lower than the p⁻ region 1001. A gate insulation film 1014 is formed on the surface layer of the p body region 1005, and a gate electrode 1010 is formed on the gate insulation film 1014. An extended drain region 1003 is formed on a part of the surface layer of the p body region 1005. The extended drain region 1003 is aligned with the edge of the gate electrode 1010. An n⁺ drain region 1009, having low resistivity, is formed on the surface layer of the extended drain region 1003. A drain electrode 1012 is formed on the surface of the n⁺ drain region 1009.

An n⁺ source region 1006, having a low resistivity, which is aligned with the edge of the opposite side of the extended drain region 1003, out of the edges of the gate electrode 1010, is formed on the surface layer of the p body region 1005. A p⁺ buried region 1007, having resistivity lower than the p⁺ body region 1005, is formed between the n⁺ source region 1006 and the BOX region 1002. A p⁺ plug region 1015, having low resistivity, is formed in a trench, which is formed from the surface of the n⁺ source region 1006 to the p⁺ substrate 1016. A source electrode 1011 is formed on the surface of the n⁻ source region 1006 and the p⁺ plug region 1015.

Now the semiconductor device in FIG. 54 will be described. The semiconductor device 1100 in FIG. 54 is one disclosed by Satoshi Matsumoto, Masato Sanno and Tatsuro Sakai in “A high efficiency 5 GHz band SOI power MOSFET having a aligned drain offset structure,” Proceedings of 2001 International Symposium on Power Semiconductor Devices & ICs, 2001, pp. 99-102, and in Japanese Patent Application Laid-Open No. 2004-111768. In the semiconductor device 1100 shown in FIG. 54, a BOX region 1102 is formed on the surface layer of a p⁻ substrate 1101. An n⁺ drain region 1112, n offset region 1108, p channel region 1107 and n⁺ source region 1110, having low resistivity, are formed on a semiconductor region contacting the surface of the BOX region 1102 (hereafter called “region on insulation film”).

A gate insulation film 1103 is formed on the surface of the p channel region 1107. A gate electrode 1104 is formed on the surface of the gate insulation film 1103. The n offset region 1108 is aligned with the drain side edge of the gate electrode 1104, and the n⁺ source region 1110 is aligned with the source side edge of the gate electrode 1104. A spacer region 1111 is aligned with the side wall of the gate electrode 1104. The n+drain region 1112 is aligned with the spacer region 1111. Silicide regions 1105, 1123 and 1124 are formed respectively on the surface of the gate electrode 1104, on the surface of the n⁺ drain region 1112, and on the surface of the n⁺ source region 1110.

In the case of the semiconductor device 1100 shown in FIG. 54, it is difficult to secure a body contact region. Therefore the layout of each region is improved, as shown in FIG. 55, for example. A semiconductor device 1200 shown in FIG. 55 is one disclosed in Japanese Patent Application Laid-Open No. 2001-068675. The semiconductor device 1200 shown in FIG. 55 is a diagram depicting a configuration of the first main surface side of a mono-crystal silicon semiconductor layer 1201. The mono-crystal silicon semiconductor layer 1201 is surrounded by a field insulation film 1226, which is formed of a silicon oxide film. A gate insulation film 1207 is formed on a part of the first main surface of the mono-crystal silicon semiconductor layer 1201.

A high density first body contact region 1214 is formed at the source region side of the gate insulation film 1207. A high density n⁺ source region 1205 is formed inside the first body contact region 1214, and the high density n⁺ source region 1205 is divided into a plurality of regions by a low density second body contact region 1225. A low density n⁻ drain offset region 1208 and high density n⁺ drain region 1212 are formed at the drain region side of the gate insulation film 1207. By forming the n⁺ source region 1205 and the second body contact region 1225 alternately like this at the source side, activation of the parasitic bipolar transistor can be suppressed.

Now a semiconductor device in FIG. 56 will be described. The semiconductor device 1300 shown in FIG. 56 is one disclosed in Japanese Patent Application Laid-Open No. S55-148464. In the semiconductor device 1300 shown in FIG. 56, a BOX region 1302 is formed on a part of a surface layer of a p⁻ substrate 1301. A gate insulation film 1303 is formed on a part of the surface of the p⁻ substrate 1301. A gate electrode 1304 is formed on the surface of the gate insulation film 1303. The BOX region 1302 is formed in an area overlapping the point where a vertical line Lc is dropped from the center of the gate electrode 1304 (gate insulation film 1303), from the edge of the drain side of the semiconductor device 1300.

An n⁺ drain region 1312 having low resistivity is formed on the surface side of the BOX region 1302. An n⁺ source region 1310 having low resistivity is formed on the surface layer of the p⁻ substrate 1301 at the side where the BOX region 1302 is formed. The n⁺ drain region 1312 aligns with the drain side edge of the gate insulation film 1304, and the n⁺ source region 1310 aligns with the source side edge of the gate insulation film 1304.

Now a semiconductor device in FIG. 57 will be described. The semiconductor device 1400 shown in FIG. 57 is one disclosed in U.S. Pat. No. 6,461,902, U.S. Pat. No. 6,667,516, by Changhong Ren, Jun Cai, Yung C. Liang, P. H. Ong, N. Balasubramanian and J. O. 0. Sin in “The partial Silicon-On-Insulator technology for RF power LDMOSFET devices and On-Chip micro-indicators,” IEEE Transactions on Electron Devices, Vol. 49, No. 12, 2002, pp. 2271-2278, and Yung C. Liang, Shuming Xu, Changhong Ren and Pang-Dow Foo in “New partial SOI LDMOS device with high power-added efficiency for 2 GHz RF power amplifier applications,” IEEE Industry Electronics Conference: IECON 2000, Vol. 2, 2000, pp. 1001-1006). In the semiconductor device 1400 shown in FIG. 57, a p⁻ region 1401 having low resistivity is formed on a p⁺ substrate 1421. A BOX region 1402 is formed in a part of the p⁻ region 1401. An n⁺ drain region 1412 and n⁻ extended drain region 1408 are formed on the surface of the BOX region 1402. Only a part of the n⁻ extended drain region 1408 at the n⁺ drain region 1412 side contacts the BOX region 1402. A drain electrode 1423 is formed on the surface of the n⁺ drain region 1412.

A gate insulation film 1403 is formed on a part of the surface of the p⁻ region 1401, and a gate electrode 1404 is formed on the gate insulation film 1403. The edge of the n⁻ extended drain region 1408 is aligned with the drain side edge of the gate electrode 1404. The edge of the n⁺ source region 1410 is matched with the source side edge of the gate electrode 1404.

A p⁺ sinker (buried portion) 1414 is formed from the surface layer of the p⁻ region 1401 to the p⁺ substrate 1421. The p⁻ sinker 1414 contacts an n⁺ source region 1410 near the surface of the p⁻ region 1401. The n⁺ source region 1410 and the p⁺ sinker 1414 are short circuited by a short circuit portion 1424. A rear face electrode region 1422 is formed on the rear surface of the p⁻ substrate 1421.

Japanese Patent Application Laid-Open No. 2004-327919 discloses a semiconductor device comprising: a semiconductor substrate; a drain region and source region including a drain offset layer formed on the main surface side of the semiconductor substrate; a field plate which is formed on a first insulation film covering a gate electrode on the drain offset layer and is electrically connected to the source region; a second insulation film which is formed on the main surface side of the semiconductor substrate and covers the field plate; a source inter-connect layer, drain inter-connect layer and gate inter-connect layer routed on the second insulation film; a third insulation film which is formed on the main surface side of the semiconductor substrate and covers the source inter-connect layer, drain inter-connect layer and gate inter-connect layer, and a source rear face electrode which is formed on the rear face of the semiconductor substrate, wherein when one edge of the drain inter-connect layer is connected to the drain electrode, one edge of the source inter-connect layer is connected to the source electrode, and the source electrode to be a ground potential is positioned between the drain electrode and the gate inter-connect layer. Japanese Patent Application Laid-Open No. 2004-103613 discloses a semiconductor device wherein a hollow region is selectively formed in a silicon substrate.

In the case of the semiconductor device according to Japanese Patent Application Laid-Open No. 2001-244476, however, the region on the insulation film is thin, which decreases the region where the device operates stably. For example, the thickness of the region on the insulation film is 0.2 to 2 μm in the semiconductor device shown in FIG. 53.

By decreasing the thickness of the region on the insulation film, the source coupling of the source region 1006 (see FIG. 53, same for the description below) becomes shallow. Also the p⁺ buried region 1007 becomes small, so the resistance between the p body region 1005 and the p⁺ plug region 1015 increases. The drain region (extended drain region 1003 and drain region 1009), the body region (p body region 1005 and p⁺ buried region 1007) and source region (n⁺ source region 1006) of the semiconductor device become a parasitic bipolar transistor.

When the drain voltage is high, holes are generated at the corner of the gate electrode 1010 (area around the interface between the p body region 1005 and the extended drain region 1003) by colliding ions. Then when the voltage drop generated between the p body region 1005 and the p⁺ plug region 1015 becomes 0.5 to 0.7 V or more, the above mentioned parasitic bipolar transistor is activated, making gate control impossible. This decreases the region where the device operates safely.

Decreasing the thickness of the region on the insulation film also deteriorates the mutual conductance of transistors and the RF frequency characteristics. As the thickness of the region of the insulation film decreases, the source coupling becomes shallow, as mentioned above, and the resistance of the n⁺ source region 1006 also increases. For example, as the circuit diagram in FIG. 58 shows, if a resistance is at the source side of the RF transistor, the effective mutual conductance gₘ of the device is given by the following Expression (1).

gₘ=gₘ₀/(1+gₘ₀·Rₛ) (1)

(gₘ₀: mutual conductance when Rₛ=0) Therefore, compared with a normal transistor, the effective mutual conductance deteriorates. Also the cut-off frequency fₜ of the device is given by the following Expression (2).

fₜ=gₘ/(2_{π}(C_{gs}+C_{gd})) (2)
(C_{gs}: capacitance between gate and source; C_{gd}: capacitance between gate and drain)
   As Expression (2) shows, the cut-off frequency decreases as the resistance Rₛ increases.

In the case of the semiconductor device according to the above mentioned Japanese Patent Applications No. 2001-244476 and No. 2004-111768 and Matsumoto et al, the BOX region exists between the region on the insulation film and the substrate, so the region on the insulation film and the substrate are completely separated. Moreover, the semiconductor device according to Japanese Patent Application Laid-Open No. 2001-244476 has a long distance between the trench penetrating the BOX region 1002 and the heat generating region. Therefore a semiconductor device according to Japanese Patent Applications Laid-Open No. 2001-244476 and No. 2004-111768 and Matsumoto et al is characterized by poor thermal dissipation.

In the case of the semiconductor device according to the above mentioned Japanese Patent Application Laid-Open No. 2004-111768 and Matsumoto et al, the n⁺ source region 1205 and the second body contact region 1225 are alternately formed at the source side, as shown in Japanese Patent Application Laid-Open No. 2001-068675. Therefore the equivalent rate width becomes short, and the current drive capability per unit area decreases.

In the case of the semiconductor device according to the above mentioned Japanese Patent Application Laid-Open No. 2004-111768 and Matsumoto et al, impurities are uniformly implanted into the p channel region 1107. Therefore density distribution, which is formed by double diffusion, is not formed, and the carrier acceleration effect, generated by dosage distribution, is lost. As a result, the carrier saturation speed region becomes smaller than the channel region formed by double diffusion, and the operation speed of the elements slows (see Francis M. Rotella, PhD. Thesis, ICL 00-095, Stanford University, 2002, pp. 83-84).

The semiconductor device according to the above mentioned Japanese Patent Application Laid-Open No. S55-148464 is suitable for a low breakdown voltage MOSFET for signal processing, but is not suitable for a high breakdown voltage device. Specifically, if high voltage is applied to the n⁺ drain region 1312, ion collision is generated at the PN junction between the n⁺ drain region 1312 and the p⁻ substrate 1301. If a hole current, generated by ion collision, flows into the p⁻ substrate 1301, the substrate potential rises, which may activate the NPN parasitic bipolar transistor comprised of the n⁺ drain region 1312, p⁻ substrate 1301 and n⁺ source region 1310. Therefore the semiconductor device according to Japanese Application Laid-Open NO. S55-148464 cannot be applied to high breakdown voltage devices.

In the case of the semiconductor device according to the above mentioned U.S. Pat. No. 6,461,902 and No. 6,667,516, Ren et al and Liang et al, the thickness of the region on the insulation film (drain region 1412 and extended drain region 1408) is limited to 6500 to 8500 Å (650 nm to 850 nm). The thickness of the BOX region 1402 is also limited to 4500 to 5500 Å (450 nm to 550 nm). If this configuration is used, the parasitic capacitance between the extended drain region 1408/drain region 1412 and the p⁻ region 1401 increases.

As FIG. 4 in Ren et al discloses, the high frequency characteristics of the device can be improved by further increases the thickness of the BOX region. However, it is difficult to form an oxide film having a several μm thickness.

It is possible to extend the BOX region 1402 down to the bottom of the gate electrode 1404, in order to decrease the parasitic capacitance between the extended drain region 1408/drain region 1412 and the p⁻ region 1401. However, the semiconductor device, according to the above mentioned Japanese Patent Application Laid-Open No. 2001-068675 and No. S55-148464, sustains a high breakdown voltage by the depletion effect from the p⁻ region 1401 by a part of the extended drain region 1408 contacting the p⁻ region 1401. Therefore if the BOX region 1402 is extended to the bottom of the gate electrode 1404, the depletion effect from the p⁻ region 1401 becomes weak, and the breakdown voltage cannot be sustained.

In view of the above, it would be preferable to provide an SOI device which has high breakdown voltage, wide stable operation range, good thermal dissipation, high effective conductance and good frequency characteristics.

### SUMMARY OF THE INVENTION

In a semiconductor device according to the present invention, a buried oxide region is formed on a part of a surface layer of a first conductive type high resistivity region. A first conductive type first semiconductor region, of which resistivity is lower than the high resistivity region, is formed on a part of the surface layer of the high resistivity region. The first semiconductor region is formed so as to contact a side face and a part of a surface layer of the buried oxide region. A gate electrode is formed on a surface of the first semiconductor region via a gate insulation film. A spacer region is formed on a side face of the gate electrode. A second conductive type low resistivity drain region is formed on a part of the surface of the buried oxide region. The low resistivity drain region is formed so as to be isolated from the first semiconductor region and the high resistivity region, and be aligned with the edge of the spacer region. A second conductive type second semiconductor region is formed on a part of the surface of the buried oxide region. The second semiconductor region is formed so as to be isolated from the high resistivity region, contact the first semiconductor region and the low resistivity drain region, and be aligned with the edge of the gate electrode at the low resistivity drain region side. A first conductive type first low resistivity region is formed on a part of the surface layer of the high resistivity region so as to be isolated from the first semiconductor region. A second conductive type low resistivity source region is formed on a part of the surface layer of the high resistivity region. The low resistivity source region is formed so as to contact the first semiconductor region and the first low resistivity region, and be aligned with the edge of the gate electrode at the first low resistivity region side. A first conductive type second low resistivity region is formed to be aligned with the edge of the spacer region at the first low resistivity region side, and to be thicker than the low resistivity source region. A first conductive type buried region is formed so as to be aligned with the edges of the gate electrode at the low resistivity drain region side and at the first low resistivity region side. A silicide region is formed on a part of the surface layer of the low resistivity drain region and a part of the surface layer of the low resistivity source region. The gate electrode, the spacer region and the silicide region are covered with an inter-layer insulation film. A drain electrode is formed so as to contact the low resistivity drain region and to cover a part of the surface layer of the inter-layer insulation film. A source electrode is formed so as to contact the low resistivity source region and cover a part of the surface layer of the inter-layer insulation film. The thickness of the low resistivity drain region and the second semiconductor region is in a 150 nm to 300 nm range.

In a semiconductor device according to the present invention, a buried oxide region is formed on a part of a surface layer of a first conductive type high resistivity region, which is formed on a first conductive type low resistivity semiconductor substrate. A first conductive type first semiconductor region, of which resistivity is lower than the high resistivity region, is formed on a part of the surface layer of the high resistivity region. The first semiconductor region is formed so as to contact a side face and a part of a surface layer of the buried oxide region. A gate electrode is formed on a surface of the first semiconductor region via a gate insulation film. A spacer region is formed on a side face of the gate electrode. A second conductive type low resistivity drain region is formed on a part of the surface of the buried oxide region. The low resistivity drain region is formed so as to be isolated from the first semiconductor region and the high resistivity region, and be aligned with the edge of the spacer region. A second conductive type second semiconductor region is formed on a part of the surface of the buried oxide region. The second semiconductor region is formed so as to be isolated from the high resistivity region, contact the first semiconductor region and the low resistivity drain region, and be aligned with the edge of the gate electrode at the low resistivity drain region side. A first conductive type first low resistivity region is formed on a part of the surface layer of the high resistivity region so as to be isolated from the first semiconductor region. A second conductive type low resistivity source region is formed on a part of the surface layer of the high resistivity region. The low resistivity source region is formed so as to contact the first semiconductor region and the first low resistivity region, and be aligned with the edge of the gate electrode at the first low resistivity region side. A first conductive type second low resistivity region is formed so as to be aligned with the edge of the spacer region at the first low resistivity region side, and to be thicker than the low resistivity source region. A first conductive type buried region is formed so as to be aligned with the edges of the gate electrode at the low resistivity drain region side and at the first low resistivity region side. A first conductive type third low resistivity region is formed in a trench which penetrates through the first low resistivity region and the high resistivity region, and reaches the low resistivity semiconductor substrate. A first conductive type fourth low resistivity region covers a periphery of the third low resistivity region. A silicide region is formed on a part of the surface layer of the low resistivity drain region and a part of the surface layer of the low resistivity source region. The gate electrode, spacer region and silicide region are covered with an inter-layer insulation film. A drain electrode is formed so as to contact the low resistivity drain region and cover a part of the surface layer of the inter-layer insulation film. A source electrode is formed so as to contact the low resistivity source region and cover a part of the surface layer of the inter-layer insulation film. The thickness of the low resistivity drain region and the second semiconductor region is in a 150 nm to 300 nm range.

In a semiconductor device according to the present invention, a buried oxide region is formed on a part of a surface layer of a first conductive type high resistivity region, which is formed on a first conductive type low resistivity semiconductor substrate. A first conductive type first semiconductor region, of which resistivity is lower than the high resistivity region, is formed on a part of the surface layer of the high resistivity region. The first semiconductor region is formed so as to contact a side face and a part of a surface of the buried oxide region. A gate electrode is formed on a surface of the first semiconductor region via a gate insulation film. A spacer region is formed on a side face of the gate electrode. A second conductive type low resistivity drain region is formed on a part of the surface of the buried oxide region. The low resistivity drain region is formed so as to be isolated from the first semiconductor region and the high resistivity region, and be aligned with the edge of the spacer region. A second conductive type second semiconductor region is formed on a part of the surface of the buried oxide region. The second semiconductor region is formed so as to be isolated from the high resistivity region, contact the first semiconductor region and the low resistivity drain region, and be aligned with the edge of the gate electrode at the low resistivity drain region side. A first conductive type first low resistivity region, which penetrates through the high resistivity region and reaches the low resistivity semiconductor substrate, is formed so as to be isolated from the first semiconductor region. A second conductive type low resistivity source region is formed on a part of the surface layer of the high resistivity region. The low resistivity source region is formed so as to contact the first semiconductor region and the first low resistivity region, and be aligned with the edge of the gate electrode at the first low resistivity region side. A first conductive type second low resistivity region is formed so as to be aligned with the edge of the spacer region at the low resistivity region side, and to be thicker than the low resistivity source region. A first conductive type buried region is formed so as to be aligned with the edges of the gate electrode at the low resistivity drain region side and at the first low resistivity region side. A silicide region is formed on a part of the surface layer of the low resistivity drain region and a part of the surface layer of the low resistivity source region. The gate electrode, spacer region and silicide region are covered with an inter-layer insulation film. A drain electrode is formed so as to contact the low resistivity drain region and cover a part of the surface layer of the inter-layer insulation film. A source electrode is formed so as to contact the low resistivity source region and cover a part of the surface layer of the inter-layer insulation film. The thickness of the low resistivity drain region and the second semiconductor region is in a 150 nm to 300 nm range.

In a semiconductor device according to the present invention, a buried oxide region is formed on a part of a surface layer of a first conductive type high resistivity region, which is formed on a first conductive type low resistivity semiconductor substrate. A first conductive type first semiconductor region, of which resistivity is lower than the high resistivity region, is formed on a part of the surface layer of the high resistivity region, so as to contact a side face and a part of a surface of the buried oxide region. A gate electrode is formed on a surface of the first semiconductor region via a gate insulation film. The gate electrode is covered with an insulation film. A second conductive type low resistivity drain region is formed on a part of the surface of the buried oxide region so as to be isolated from the first semiconductor region and the high resistivity region. A second conductive type second semiconductor region is formed on a part of the surface of the buried oxide (insulation) region, so as to be isolated from the high resistivity region and contact the first semiconductor region and the low resistivity drain region. A first conductive type first low resistivity region is formed on a part of the surface layer of the high resistivity region so as to be isolated from the first semiconductor region. A second conductive type low resistivity source region is formed on a part of the surface layer of the high resistivity region, so as to contact the first semiconductor region and the first low resistivity region. A first conductive type second low resistivity region is formed so as to be aligned with the edge of the spacer region at the first low resistivity region side, and to be thicker than the low resistivity source region. A drain electrode is formed so as to contact the low resistivity drain region and cover a part of the surface of an inter-layer insulation film. A source electrode is formed so as to contact the low resistivity source region and cover a part of the surface of the inter-layer insulation film. The buried oxide region extends to a position overlapping the gate electrode.

The buried oxide region is formed of silicon dioxide, for example. If the buried oxide region is formed of silicon dioxide, the thickness of the buried oxide region is 400 nm or more. The buried oxide region may be a depletion layer. If the buried oxide region is a SON (Silicon-ON-Nothing) layer, the thickness of the buried oxide region is 150 nm or more. The thickness of the gate insulation film may be thicker at the edge side of the gate electrode than at the center side of the gate electrode.

According to the semiconductor device of the present invention, the region on the insulation film (i.e., the region on the buried oxide region) and the high resistivity region are separated via the buried oxide region, so activation of the parasitic bipolar transistor can be prevented, and a semiconductor device having a large safe operation region can be obtained. Also the region on the insulation film and the high resistivity semiconductor substrate are not completely separated, so thermal dissipation can be improved.

According to a fabrication method for a semiconductor device of the present invention, when the semiconductor device having the above mentioned configuration is fabricated, the gate electrode is formed, via the gate insulation film, on the surface of the high resistivity semiconductor substrate a part of which is formed with the buried oxide film. Then the surface of the gate electrode at the buried oxide region side and the surface of the high resistivity semiconductor substrate at the buried oxide region side are covered with photo resist. The first semiconductor region is formed by implanting first conductive type ions into the surface layer of the high resistivity semiconductor substrate. After removing the photo resist from the high resistivity semiconductor substrate on which the first semiconductor region is formed, the low resistivity drain region is formed by implanting second conductive type ions into the surface layer of the high resistivity semiconductor substrate. The spacer region is formed on the side face of the gate electrode on the surface of the high resistivity semiconductor substrate on which the low resistivity region is formed. Then the second semiconductor region is formed by implanting second conductive type ions into the surface layer of the high resistivity semiconductor substrate.

According to a fabrication method for a semiconductor device of the present invention, when the semiconductor device having the above mentioned configuration is fabricated, a pseudo-gate electrode is formed, via the gate insulation film, on the surface of the high resistivity semiconductor substrate a part of which is formed with the buried oxide film. Then the surface of the pseudo-gate electrode at the buried oxide region side and the surface of the high resistivity semiconductor substrate at the buried oxide region side are covered with photo resist. The first semiconductor region is formed by implanting first conductive type ions into the surface layer of the high resistivity semiconductor substrate. After removing the photo resist from the high resistivity semiconductor substrate on which the first semiconductor region is formed, the low resistivity drain region is formed by implanting second conductive type ions into the surface layer of the high resistivity semiconductor substrate. The spacer region is formed on the side face of the pseudo-gate electrode on the surface of the high resistivity semiconductor substrate on which the low resistivity region is formed. After the spacer region is formed, the second semiconductor region is formed by implanting second conductive type ions into the surface layer of the high resistivity semiconductor substrate. Then the gate electrode is formed after removing the pseudo-gate electrode.

According to the fabrication method for a semiconductor device of the present invention, the first semiconductor region and the low resistivity drain region can be formed using the gate electrode or the pseudo-gate electrode as a mask, so the fabrication efficiency of the semiconductor device can be improved.

According to the fabrication method for a semiconductor device of the present invention, when the semiconductor device having the above mentioned configuration is fabricated, a device structure is formed on the high resistivity semiconductor substrate a part of which is formed with the buried oxide region formed of silicon dioxide. In a further embodiment of the invention, the SON layer is formed by removing the silicon dioxide by etching.

According to the fabrication method for a semiconductor device of the present invention, in the case where the buried oxide region is a SON layer, the semiconductor device can be fabricated by etching the high resistivity semiconductor substrate, a part of which is formed with the buried oxide region formed of silicon dioxide.

According to the semiconductor device of the present invention, an SOI device, having high breakdown voltage, wide safe operation range, good thermal dissipation, high effective conductance and good frequency characteristics, can be obtained.

### BRIEF DESCRIPTION OF THE DRAWINGS

The invention will be described with respect to certain preferred embodiments and the accompanying drawings, wherein:

FIG. 1 is a diagram depicting a configuration of a semiconductor device according to Embodiment 1;

FIG. 2 is a diagram depicting fabrication of a partial SOI substrate for the semiconductor device according to Embodiment 1;

FIG. 3 is a diagram depicting fabrication of a gate structure for the semiconductor device according to Embodiment 1;

FIG. 4 is a diagram depicting ion implantation in the fabrication of the semiconductor device according to Embodiment 1;

FIG. 5 is a diagram depicting formation of a p body region in the fabrication of the semiconductor device according to Embodiment 1;

FIG. 6 is a diagram depicting ion implantation in the fabrication of the semiconductor device according to Embodiment 1;

FIG. 7 is a diagram depicting formation of an extended drain region and ion implantation in the fabrication of the semiconductor device according to Embodiment 1;

FIG. 8 is a diagram depicting formation of a p buried region and ion implantation in the fabrication of the semiconductor device according to Embodiment 1;

FIG. 9 is a diagram depicting formation of an n⁺ source region and film deposition in the fabrication of the semiconductor device according to Embodiment 1;

FIG. 10 is a diagram depicting formation of a gate side wall spacer and ion implantation in the fabrication of the semiconductor device according to Embodiment 1;

FIG. 11 is a diagram depicting formation of an n⁺ drain region and ion implantation in the fabrication of the semiconductor device according to Embodiment 1;

FIG. 12 is a diagram depicting formation of a p⁺ buried region and ion implantation in the fabrication of the semiconductor device according to Embodiment 1;

FIG. 13 is a diagram depicting formation of a p⁺ body contact region in the fabrication of the semiconductor device according to Embodiment 1;

FIG. 14 is a diagram depicting silicide formation in the fabrication of the semiconductor device according to Embodiment 1;

FIG. 15 is a diagram depicting formation of an insulating film in the fabrication of the semiconductor device according to Embodiment 1;

FIG. 16 is a diagram depicting a configuration of a semiconductor device according to Embodiment 2;

FIG. 17 is a diagram depicting a configuration of a semiconductor device according to Embodiment 3;

FIG. 18 is a diagram depicting a structure of a part of the SOI substrate used for fabrication of the semiconductor device according to Embodiment 2 and Embodiment 3;

FIG. 19 is a diagram depicting a configuration of a semiconductor device according to Embodiment 4;

FIG. 20 is a diagram depicting a cross-sectional view at the A-A′ line in the layout diagram of the semiconductor device shown in FIG. 22according to Embodiment 4;

FIG. 21 is a diagram depicting a cross-sectional view sectioned at the B-B′ line in the layout diagram of the semiconductor device shown in FIG. 22 according to Embodiment 4;

FIG. 22 is a diagram depicting photolithography and anisotropic etching in fabrication of a semiconductor device according to Embodiment 4;

FIG. 23 is a diagram depicting film deposition in the fabrication of a semiconductor device according to Embodiment 4 in a cross-sectional view sectioned at the A-A′ line as shown in FIG. 22;

FIG. 24 is a diagram depicting removal of a portion of film in the fabrication of a semiconductor device according to Embodiment 4 in a cross-sectional view sectioned at the B-B′ line as shown in FIG. 22;

FIG. 25 is a diagram depicting etching in the fabrication of a semiconductor device according to Embodiment 4 in a cross-sectional view sectioned at the A-A′ line as shown in FIG. 22;

FIG. 26 is a diagram depicting etching in the fabrication of a semiconductor device according to Embodiment 4 in a cross-sectional view sectioned at the B-B′ line as shown in FIG. 22;

FIG. 27 is a diagram depicting formation of a SON layer in the fabrication of a semiconductor device according to Embodiment 4 in a cross-sectional view sectioned at the A-A′ line as shown in FIG. 22;

FIG. 28 is a diagram depicting formation of a SON layer in the fabrication of a semiconductor device according to Embodiment 4 in a cross-sectional view sectioned at the B-B′ line as shown in FIG. 22;

FIG. 29 is a diagram depicting formation of an inter-layer insulation film in the fabrication of a semiconductor device according to Embodiment 4 in a cross-sectional view sectioned at the A-A′ line as shown in FIG. 22;

FIG. 30 is a diagram depicting formation of an inter-layer insulation film in the fabrication of a semiconductor device according to Embodiment 4 in a cross-sectional view sectioned at the B-B′ line as shown in FIG. 22;

FIG. 31 is a graph depicting a relationship of a thickness of the BOX region or SON layer and a maximum oscillation frequency;

FIG. 32 is a graph depicting a relationship of a thickness of the BOX region or SON layer and a peak value of the cut-off frequency, and a relationship of a thickness of the BOX region or SON layer and a maximum oscillation frequency;

FIG. 33 is a diagram depicting a configuration of a semiconductor device according to Embodiment 5;

FIG. 34 is a diagram depicting a configuration of a semiconductor device according to Embodiment 6;

FIG. 35 is a diagram depicting a configuration of a semiconductor device according to Embodiment 7;

FIG. 36 is a diagram depicting formation of a gate insulation film and dummy gate structure in fabrication of a semiconductor according to Embodiment 7;

FIG. 37 is a diagram depicting ion implantation in the fabrication of a semiconductor according to Embodiment 7;

FIG. 38 is a diagram depicting formation of a p body region in the fabrication of a semiconductor according to Embodiment 7;

FIG. 39 is a diagram depicting ion implantation in the fabrication of a semiconductor according to Embodiment 7;

FIG. 40 is a diagram depicting formation of an extended drain region and ion implantation in the fabrication of a semiconductor according to Embodiment 7;

FIG. 41 is a diagram depicting formation of a p buried region and ion implantation in the fabrication of a semiconductor according to Embodiment 7;

FIG. 42 is a diagram depicting formation of an n⁺ source region and film deposition in the fabrication of a semiconductor according to Embodiment 7;

FIG. 43 is a diagram depicting formation of a gate side wall spacer and ion implantation in the fabrication of a semiconductor according to Embodiment 7;

FIG. 44 is a diagram depicting formation of an n⁺ drain region, an n⁺ source region and an inter-layer insulation film in the fabrication step of a semiconductor according to Embodiment 7;

FIG. 45 is a diagram depicting exposure of the dummy gate structure in the fabrication of a semiconductor according to Embodiment 7;

FIG. 46 is a diagram depicting removal of the dummy gate structure and gate insulation film directly underneath in the fabrication step of a semiconductor according to Embodiment 7;

FIG. 47 is a graph depicting a relationship of a source side edge position of the BOX region and a peak value of a cut-off frequency, and a relationship of a source side edge position of the BOX region and a maximum oscillation frequency in a device having the BOX region;

FIG. 48 is a graph depicting a relationship of a source side edge position of a SON layer and a peak value of a cut-off frequency, and a relationship of a source side edge position of a SON layer and a maximum oscillation frequency in a device having a SON layer;

FIG. 49 is a graph depicting a simulation result of a maximum internal temperature of the semiconductor device according to the present invention, and the semiconductor device according to prior art;

FIG. 50 is a diagram depicting an impurity density distribution of the semiconductor device according to the present invention;

FIG. 51 is a diagram depicting an impurity density distribution of the semiconductor device according to prior art;

FIG. 52 is a diagram depicting a configuration of a thermal circuit used for the simulation in FIG. 49;

FIG. 53 is a diagram depicting an example of a configuration of a thin film SOI device having a conventional structure;

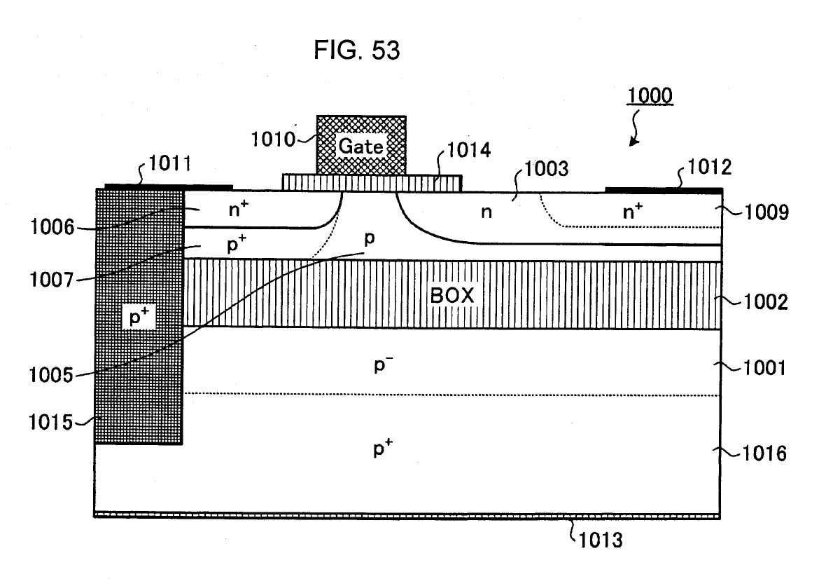

FIG. 54 is a diagram depicting an example of a configuration of a thin film SOI device having a conventional structure;

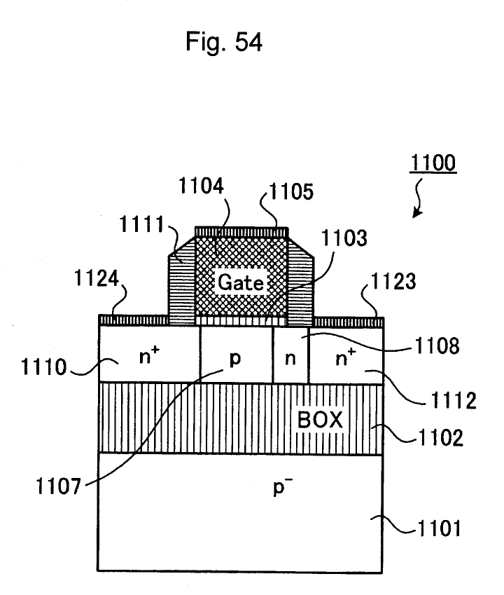

FIG. 55 is a diagram depicting an example of a configuration of a thin film SOI device having a conventional structure;

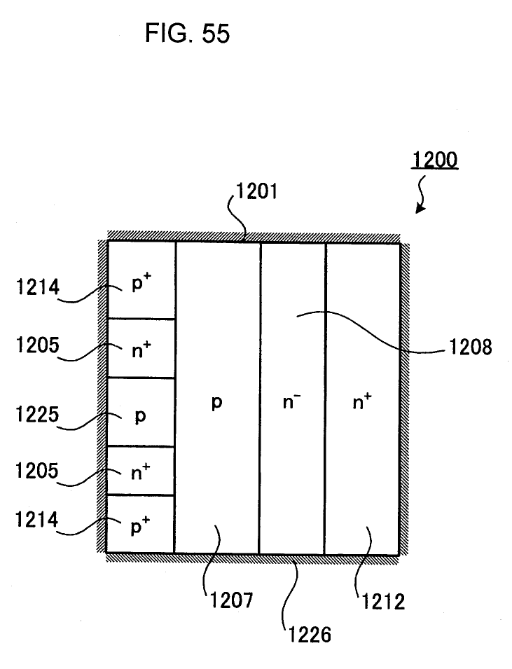

FIG. 56 is a diagram depicting an example of a configuration of a thin film SOI device having a conventional structure;

FIG. 57 is a diagram depicting an example of a configuration of a thin film SOI device having a conventional structure; and

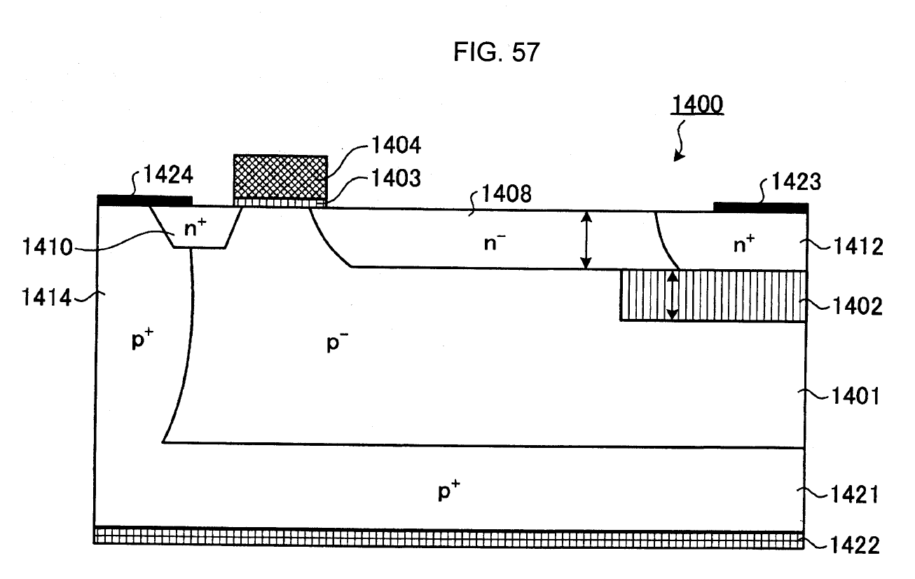

FIG. 58 is a circuit diagram depicting a characteristic of a thin film SOI device having a conventional structure.

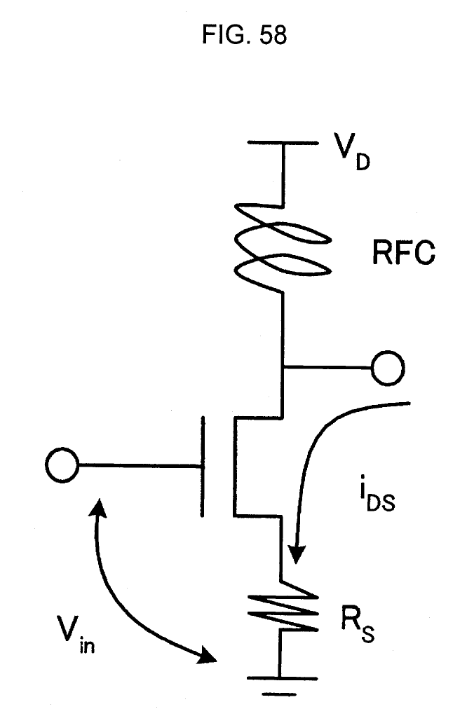

### DESCRIPTION OF THE PREFERRED EMBODIMENTS

Embodiments of the semiconductor device according to the present invention will now be described with reference to the accompanying drawings. In the following embodiments, the same composing elements are denoted with a same reference symbol, and detailed description thereof is omitted.

### Embodiment 1

Configuration of semiconductor device 100

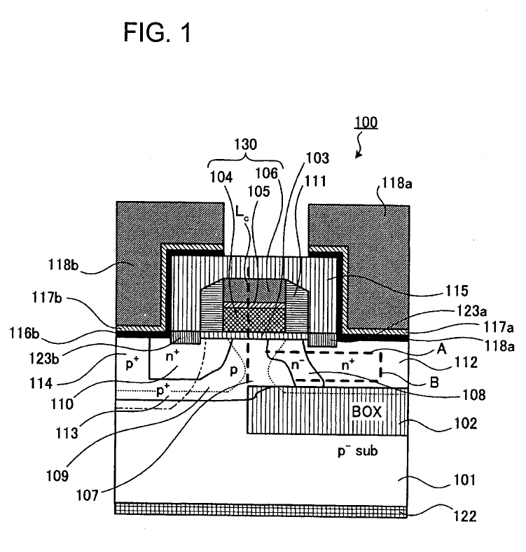

FIG. 1 is a diagram depicting a configuration of a semiconductor device according to Embodiment 1. In the semiconductor device 100 shown in FIG. 1, a buried oxide region (BOX region) 102 is formed in a part of a region of a p substrate 101 having high resistivity. The BOX region 102 is specifically formed in a region from a drain side of the semiconductor device 100 to below a gate structure portion 130. More specifically, the BOX region 102 is formed in a region around the vertical line Lc dropped from a center between the source side edge and the drop side edge of the gate structure portion 130. The BOX region 102 is formed of silicon dioxide (SiO₂), for example.

An n⁺ drain region 112, extended drain region 108 and p body region 107 are formed on the surface of the BOX region 102 (collectively referred to as region on the insulation film) sequentially toward the center area of the semiconductor device 100. The n⁺ drain region 112 and extended drain region 108 are isolated from the p⁻ substrate 101 by the BOX region 102. The surface of the p body region 107 is covered with a gate insulation film 103. The gate structure portion 130 comprised of a high density polysilicon section 104, a barrier film 105 formed of titanium nitride (TiN) and a tungsten polyside portion 106, is formed on the gate insulation film 103. The gate structure portion 130 may be formed of metal material. A gate side wall spacer 111 is formed of a nitride film or oxide film on the side face of the gate structure portion 130.

The gate insulation film 103 is formed so as to cover the bottom faces of the gate structure portion 130 and the gate side wall spacer 111. A silicide region 123a is formed at the drain side of the gate insulation film 103 so as to contact the n⁺ drain region 112. A silicide region 123b is formed at the source side of the gate insulation film 103 so as to contact a later mentioned n⁺ source region 110.

The resistivities of the n⁺ drain region 112, extended drain region 108 and p body region 107 are all lower than that of the p⁻ substrate 101. The extended drain region 108 is aligned with the drain side edge of the gate structure portion 130. The n⁺ drain region 112 is aligned with the drain side edge of the gate side wall spacer 111. A p buried region 109 is formed so as to be aligned with the drain side edge section and the source side edge section of the gate structure portion 130.

The n⁺ source region 110 is formed in a region on the p⁻ substrate 101 where the BOX region 102 is not formed. The n⁺ source region 110 is aligned with an opposite edge of the gate structure portion 130 from the edge with which the n⁺ drain region 112 is aligned. A p⁺ buried region 113 is formed so as to be aligned with the source side edge of the gate side wall spacer 111. The p⁺ buried region 113 is formed to be thicker than the n⁺ source region 110. A p⁺ body contact region 114 is formed so as to contact the n⁺ source region 110. The thickness of the p⁺ body contact region 114 reaches the p⁺ buried region 113.

An inter-layer insulation film 115 is formed so as to cover the gate insulation film 103 and the gate structure portion 130. A titanium (Ti) silicide layer 116a and a titanium nitride (TiN) barrier layer 117a are formed so as to contact a part of the surface of the n⁺ drain region 112, and extend to the top face of the inter-layer insulation film 115. An aluminum (Al) drain electrode 118a is formed on the surface of the silicide layer 116a and the barrier layer 117a. A titanium (Ti) silicide layer 116b and a titanium nitride (TiN) barrier layer 117b are formed so as to contact a part of the surface of the n⁺ source region 110 and the surface of the p⁺ body contact region 114, and extend to the top face of the inter-layer insulation film 115. An aluminum (Al) source electrode 118b is formed on the surface of the silicide layer 116b and the barrier layer 117b. A rear face electrode 122 is formed on the rear face of the p⁻ substrate 101.

As mentioned above, in the semiconductor device 100, the extended drain region 108 and the p⁻ substrate 101 are separated by the BOX region 102. Therefore the parasitic capacitance between the extended drain region 108 and the p⁻ substrate 101 can be decreased. The BOX region 102 is not formed at the source side of the semiconductor device 100, so the area for the n⁺ source region 110 and the p⁺ buried region 113 can be secured.

The p body region 107 of the semiconductor device 100 is formed by ion implantation from the source side. By this, the electric field distribution for accelerating electronic conduction is formed by the spatial distribution of the impurities. The p buried region 109 of the semiconductor device is formed by implanting ions diagonally so as to aligned with the gate structure portion 130. By this, the depletion layer does not spread below the gate structure portion 130 very much, and the feedback capacitance of the device is decreased, and also the channel length modulation effect and the short channel effect can be decreased. Moreover, the activation of the parasitic bipolar transistor can be suppressed, and a region where the device can operate safely can be expanded.

The silicon device 100 can suppress the drain-induced barrier lowering (DIBL) effect, so the breakdown voltage of the device can be improved without two-dimensionally converging the electrostatic power lines of the extended drain region 108 into the p body region 107, as in the case of a silicon bulk device. The drain-induced barrier lowering effect here refers to a phenomenon where the potential barrier between the source and drain (band structure) becomes small due to the power lines emitted from the drain because of the increase in drain voltage. If a drain-induced barrier lowering effect is generated, leak current increases and without stand voltage drops.

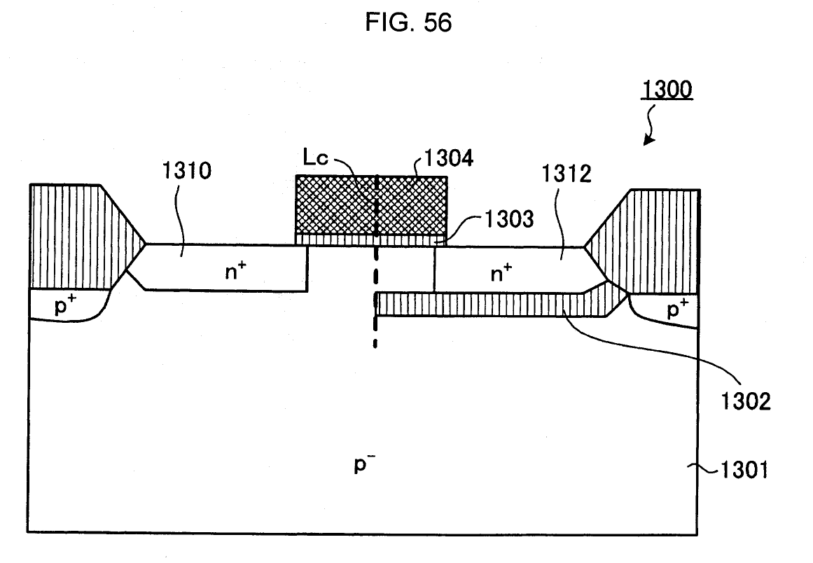

In the semiconductor device 100, the p⁻ buried region 113 is formed below the n⁺ source region 110, so the parasitic bipolar transistor, comprised of the n⁺ drain region 112, extended drain region 108, p body region 107 and n⁺ source region 110, is hardly activated. Therefore unlike the semiconductor device of Japanese Patent Application Laid-Open No. S55-148464 (see FIG. 56), the semiconductor device 100 can be applied to a high breakdown voltage device.

If the extended drain region 108 is completely surrounded by a dielectric substance, the major breakdown voltage paths are the first path indicated by A and the second path indicated by B in FIG. 1. A breakdown voltage path here refers to a path of which path integration of the collision ionization coefficient easily (that is, a breakdown). The breakdown voltage of the second path increases as the thickness of the region on the insulation film decreases (see S. Merchant, E. Arnold, H. Baumgart, S. Mukherjee, H. Pein, R. Pinker, “Realization of High Breakdown Voltage (>700V) in a Thin SOI Device”, Proc. Third Int. Symp. On Power Semiconductor Devices and ICs, 1991, pp. 31-35). Therefore in the semiconductor device 100, the thickness of the region on the insulation film is set to 150 nm to 300 nm (1500 Å to 3000 Å), so as to improve breakdown voltage. If the BOX region 102 is formed of silicon dioxide, the thickness of the BOX region 102 is set to 400 nm (4000 Å) or more. By this, the parasitic capacitance between the extended drain region 108/drain region 112 and the p⁻ substrate 101 is reduced. Fabrication Method for Semiconductor Device 100

An example of the fabrication method for the semiconductor device 100 will now be described. The fabrication method for the semiconductor device 100, however, is not limited to the process described herein below.

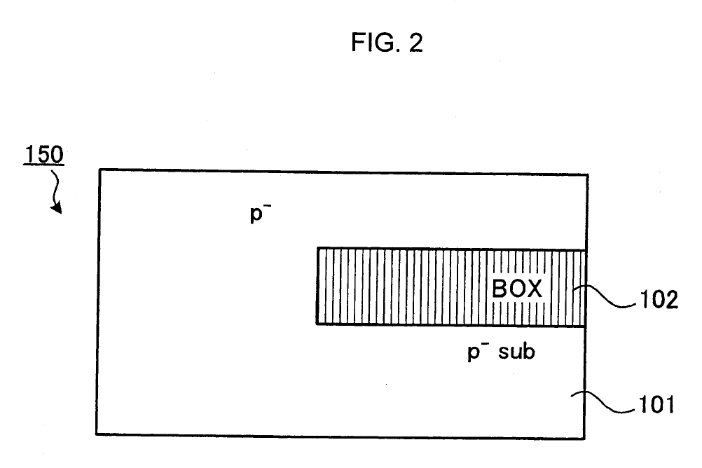

FIG. 2 to FIG. 15 are diagrams depicting the fabrication of the semiconductor device according to Embodiment 1. As shown in FIG. 2, a partial SOI substrate 150, on which the BOX region 102 is partially formed on the p⁻ substrate 101, is provided, as shown in FIG. 2. The partial SOI substrate 150 can be formed by various known technologies.

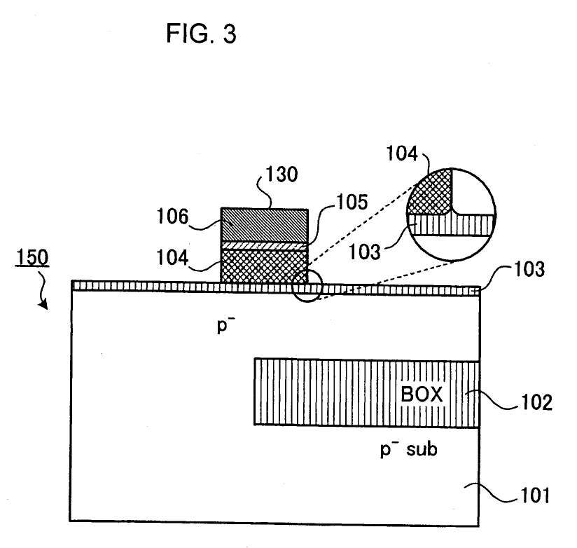

Then, as shown in FIG. 3, the gate insulation film 103 is grown on the surface of the partial SOI substrate 150, and then the polysilicon portion 104, barrier film 105 and tungsten polyside portion 106 are deposited on the surface of the gate insulation film 103. Then photolithography and reactive ion etching (RIE) are performed, so as to form the gate structure portion 130 on the surface of the partial SOI substrate 150. At this time, the portion of the gate insulation film 103, which covers the gate electrode edge (gate corner), is thickened by shadow oxidation. An alternative way is depositing a nitride film on the entire surface of the partial SOI substrate 150, and then covering the surface of the oxide film at the source region side by photolithography and etching and performing thermal oxidation, so as to thicken the gate corner of the gate insulation film 103 at the drain side.

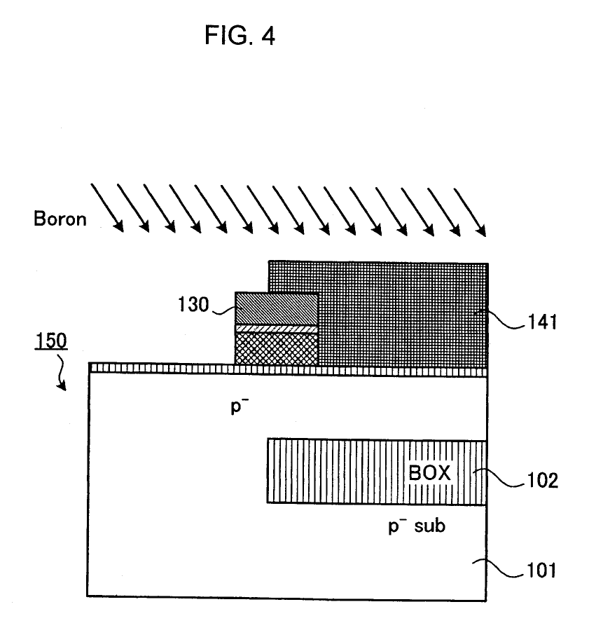

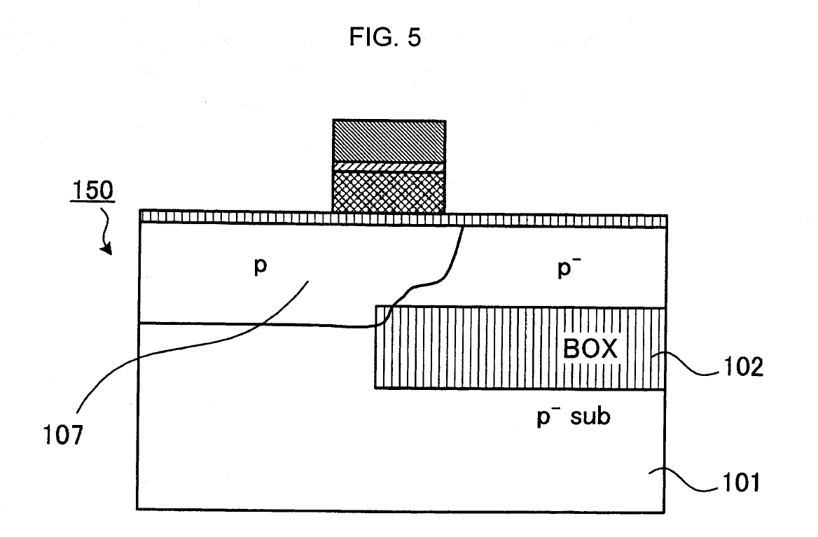

Then as FIG. 4 shows, the surface of the gate structure portion 130 at the drain side and the surface of the partial SOI substrate 150 at the drain side are covered with photo resist 141 by photolithography. Then boron (B) ions are implanted diagonally (at a 45° angle into the surface of the partial SOI substrate 150) from the source side. After removal of the photo resist 141 and cleaning, diffusion is performed and the p body region 107 is formed, as shown in FIG. 5.

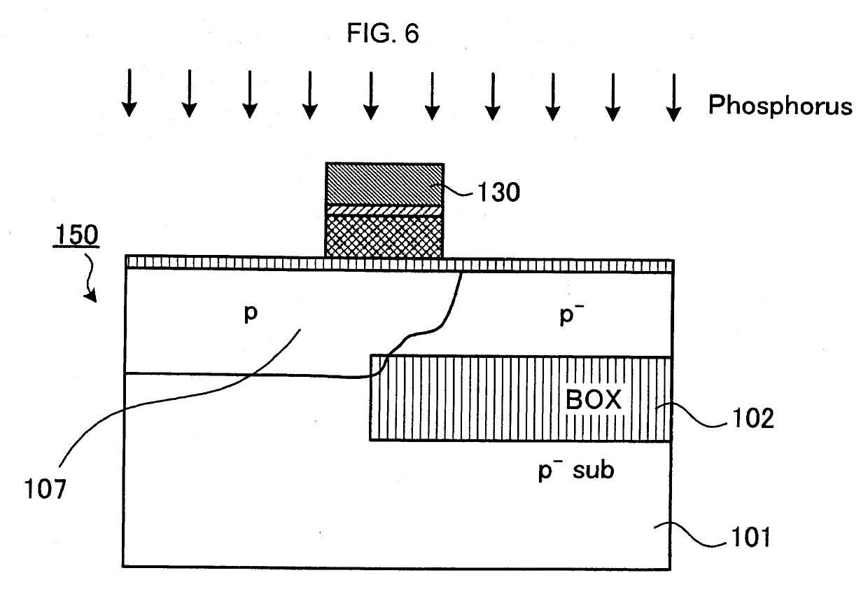

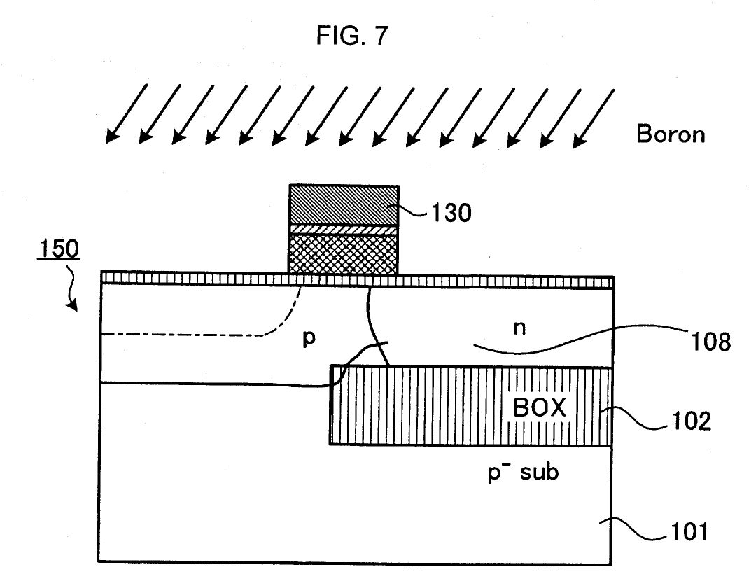

Then as FIG. 6 shows, phosphorus (P) ions are implanted in a vertical direction into the surface of the partial SOI substrate 150 using the gate structure portion 130 as a mask, so as to align with the gate structure portion 130. Diffusion is performed by thermal processing or Rapid Thermal Annealing (RTA), and the extended drain region 108 (see FIG. 7) is formed.

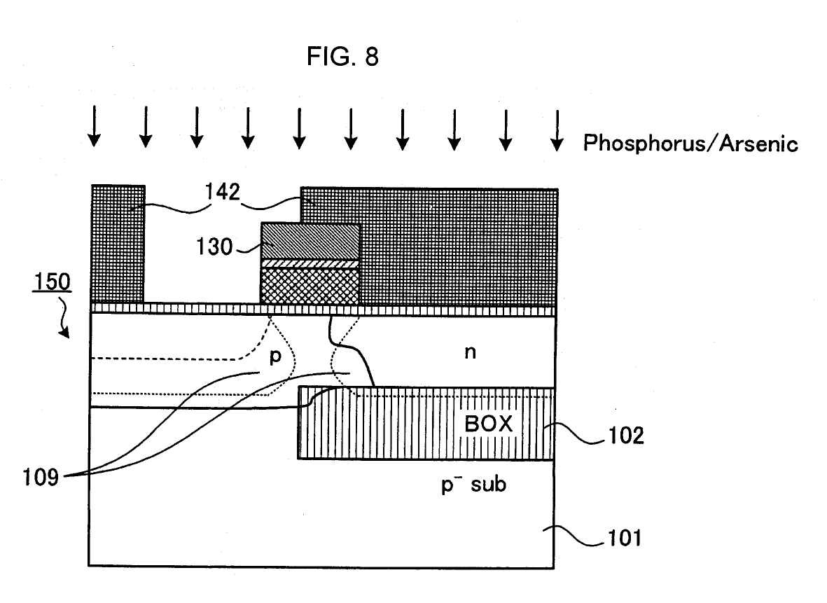

Then as FIG. 7 shows, boron (B) ions or boron difluoride (BF₂) is implanted diagonally from the drain side (e.g. 30° angle into the surface of the partial SOI substrate 150), so as to align with the gate structure portion 130. Diffusion is performed, and the p buried region 109 (see FIG. 8) is formed.

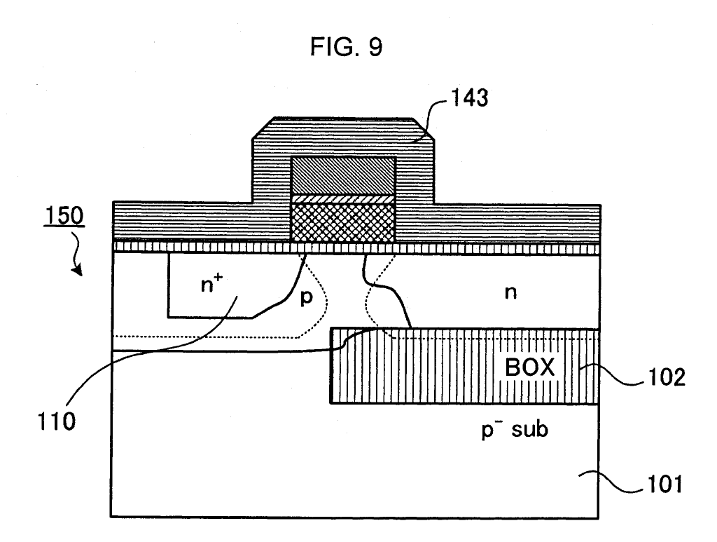

Then as FIG. 8 shows, a part of the surface of the partial SOI substrate 150 at the source side (surface of a portion to be the p⁺ body contact region 114 in FIG. 1), a part of the gate structure portion 130 at the drain side, and a part of the surface of the region, where the extended drain region 108 is formed, are covered with photo resist 142 by photolithography. Then phosphorus (P) or arsenic (As) ions are implanted vertically into the surface of the partial SOI substrate 150, and the n⁺ source region 110 (see FIG. 9) is formed.

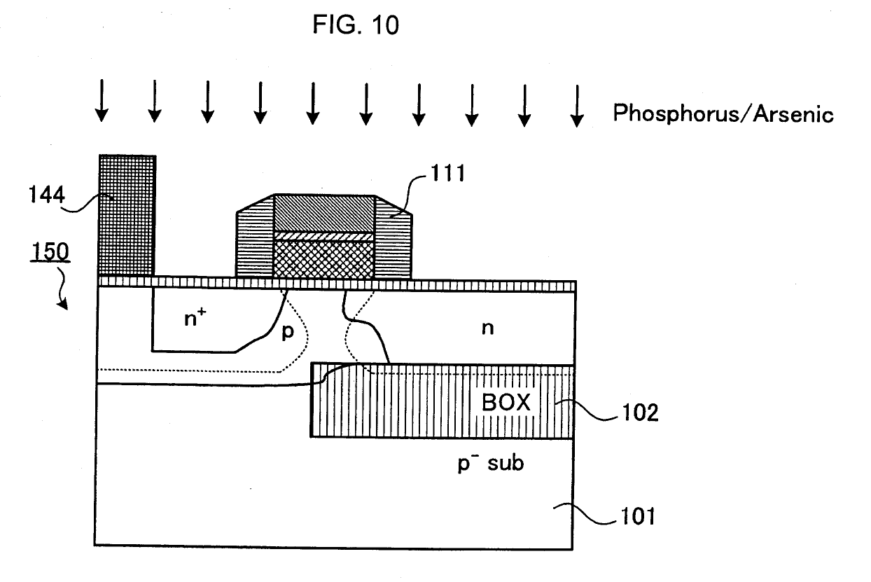

Then as FIG. 9 shows, after removal of the photo resist 142 and cleaning, a 300 nm thick oxide film or nitride film 143 is deposited on the entire surface of the partial SOI substrate 150. Then anisotropic etching is performed on this oxide film or nitride film 143, and the gate side wall spacer 111 is formed (see FIG. 10).

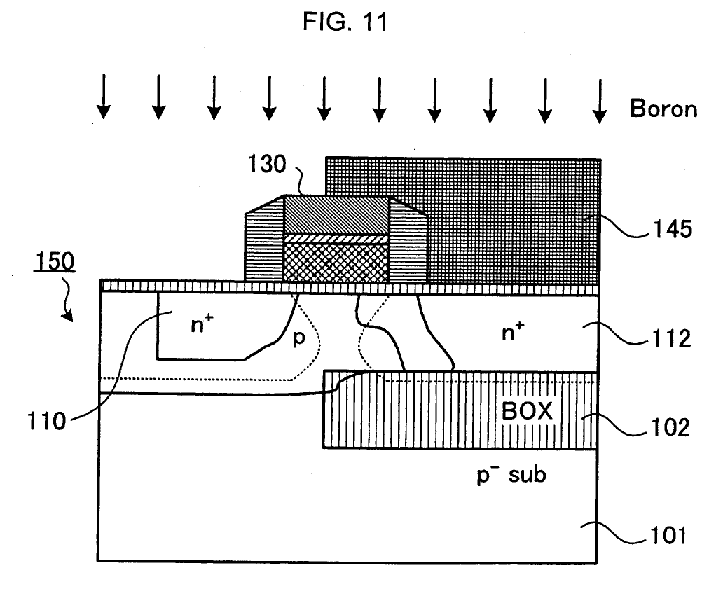

Then as FIG. 10 shows, a part of the surface of the partial SOI substrate 150 at the source side (surface of the portion to be the p⁺ body contact region 114 in FIG. 1) is covered with the photo resist 144 by photolithography. Using the gate structure portion 130 and the gate side wall spacer 111 as masks, phosphorus (P) or arsenic (As) ions are implanted vertically into the surface of the partial SOI substrate 150, so as to align with the gate side wall spacer 111. After removing the photo resist 144, diffusion is performed by thermal processing or RTA, and the n⁺ drain region 112 (see FIG. 11) is formed.

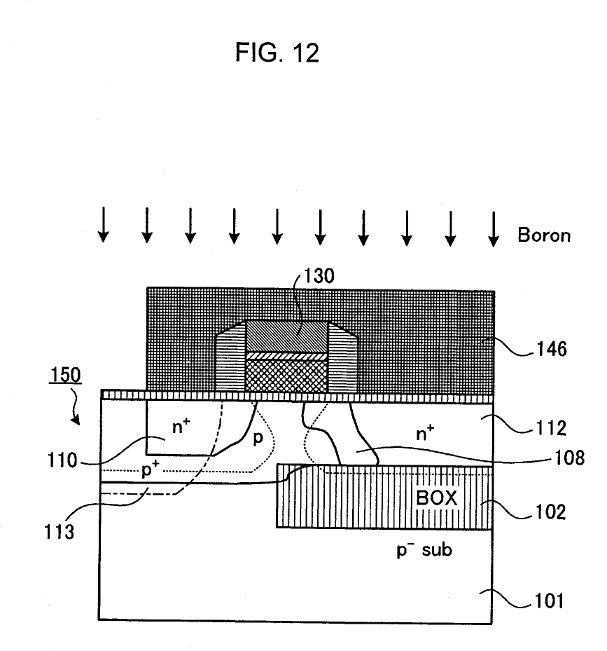

Then as FIG. 11 shows, a part of the surface of the partial SOI substrate 150 (surface of the region where the extended drain region 108 and the n⁺ drain region 112 are formed) and the surface of the gate structure portion 130 at the drain side are covered with the photo resist 145 by photolithography. Then boron (B) ions are implanted vertically into the surface of the partial SOI substrate 150. The acceleration energy of the boron ions at this time is 90 keV, for example. After removal of the photo resist 145 and cleaning, activation is performed by RTA, and the p⁺ buried region 113 (see FIG. 12) is formed.

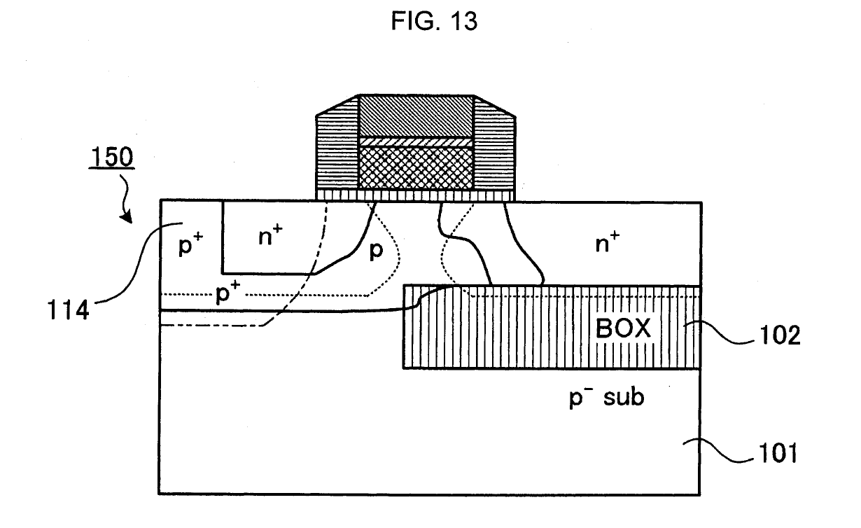

Then as FIG. 12 shows, a part of the surface of the partial SOI substrate 150 (surface of the region where the n⁺ source region 110, extended drain region 108 and drain region 112 are formed) and the surface of the gate structure portion 130 are covered with the photo resist 146 by photolithography. Then boron (B) ions are implanted vertically into the surface of the partial SOI substrate 150. After removal of the photo resist 146 and cleaning, activation is performed by RTA, and the p⁺ body contact region 114 is formed, as shown in FIG. 13.

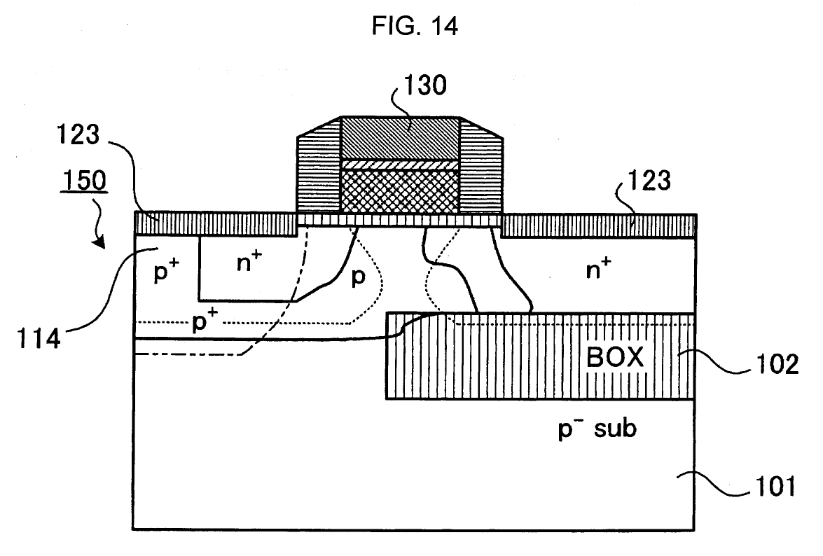

Then as FIG. 14 shows, a thin film of titanium (Ti) or cobalt (Co) is deposited on the surface of the partial SOI substrate 150 (excluding the area where the gate structure portion 130 is formed). After thermal processing, the titanium or cobalt thin film is selectively removed to form the silicide 123.

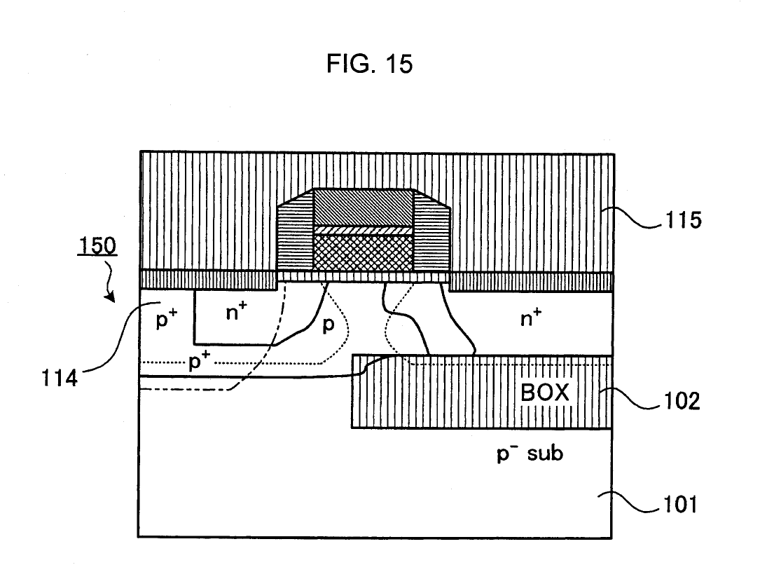

Then as FIG. 15 shows, the inter-layer insulation film 115 is deposited on the entire surface of the partial SOI substrate 150. Then a contact is formed by photolithography and etching, a contact protective layer (e.g. titanium (Ti), titanium nitride (TiN)) is formed on the entire surface of the partial SOI substrate 150, and then an aluminum (Al) interconnect layer containing silicon (Si) and copper (Cu) components is deposited. And a first metal layer is formed by photolithography and etching. Then if necessary, a multi-layer metal process is performed, and the silicide layers 116a, 116b, barrier layers 117a, 117b, drain electrode 118a and source electrode 118b are formed. Then the rear face electrode 122 (see FIG. 1) is formed. By the above process, the semiconductor device 100, according to Embodiment 1 shown in FIG. 1, can be fabricated.

This semiconductor device 100 is suitable for an integrated type device. If the width of the extended drain region 108 is 0.3 μm, for example, a device of which breakdown voltage is about 16V can be obtained. This device is suitable for a power amplification device of a mobile radio communication terminal, of which power supply is a one cell Li ion/polymer battery (3.6V).

### Embodiment 2

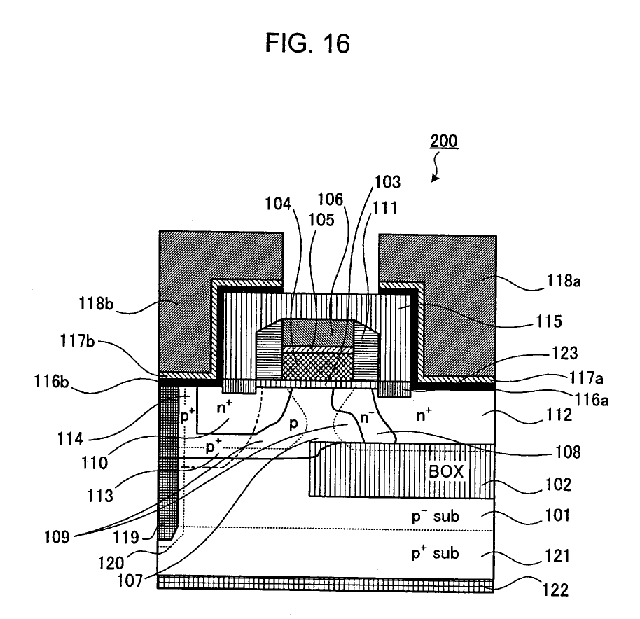

FIG. 16 is a diagram depicting a configuration of a semiconductor device according to Embodiment 2. Aspects that are different from the semiconductor device 100 of Embodiment 1 will be described for the configuration of the semiconductor device 200 shown in FIG. 16. In the semiconductor device 200, a p⁻ region (p⁻ substrate) 101 having high resistivity is formed on a p⁺ substrate 121 having low resistivity, and a BOX region 102 is formed on a part of a surface layer of the p⁻ region 101.

In a trench which is formed from a surface of a p⁺ body contact region 114 to the p⁺ substrate 121, a p⁺ plug region 119, made of polysilicon having low resistivity, is formed. Around the trench where the p⁻ plug region 119 is formed, a p⁺ diffusion region 120 is formed by the diffusion of impurities from the p⁺ plug region 119. This semiconductor device 200 is suitable for a discrete device, for example.

### Embodiment 3

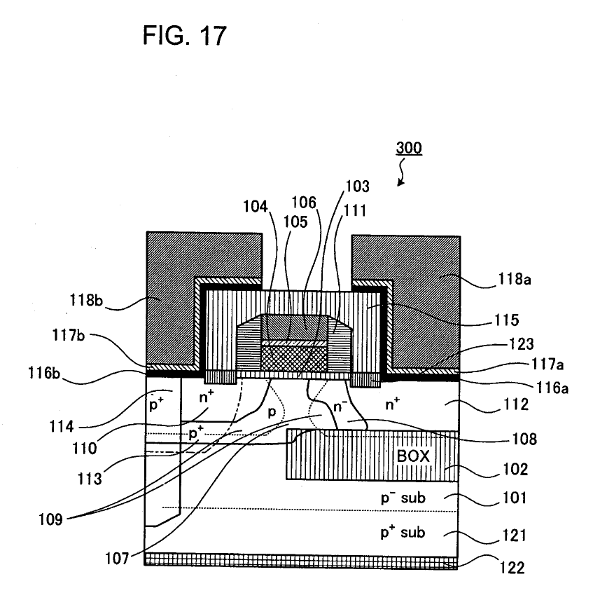

FIG. 17 is a diagram depicting a configuration of a semiconductor device according to Embodiment 3. Aspects that are different from the semiconductor device 100 of Embodiment 1 will be described for the configuration of the semiconductor device 300 shown in FIG. 17. In the semiconductor device 300, a p⁻ region (p⁻ substrate) 101 having high resistivity is formed on a p⁺ substrate 121 having low resistivity, just like the semiconductor device 200 of Embodiment 2, and a BOX region 102 is formed on a part of a surface layer of the p⁻ region 101.

In the semiconductor device 300, a p⁺ body contact region 114 penetrates through the p⁻ region 101, and reaches the p⁺ substrate 121. This semiconductor device 300 is suitable for a discrete device, for example.

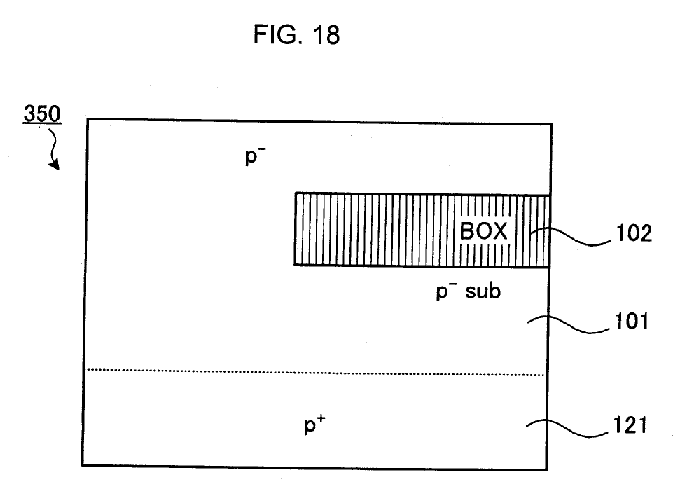

To fabricate the semiconductor device according to Embodiment 2 or Embodiment 3, a partial SOI substrate 350 shown in FIG. 18 is used instead of the partial SOI substrate 150 shown in FIG. 2. FIG. 18 is a diagram depicting a structure of the partial SOI substrate used for fabricating the semiconductor device according to Embodiment 2 or Embodiment 3. In the partial SOI substrate 350 used for fabrication of the semiconductor device of Embodiment 2 or Embodiment 3, a p⁻ region (p⁻ substrate) 101 having high resistivity is formed on the p⁺ substrate 121 having low resistivity, and the BOX region 102 is formed on a part of the surface layer of the p⁻ region 101.

To fabricate the semiconductor device according to Embodiment 2 or Embodiment 3, the processing shown in FIG. 3 to FIG. 15 is performed on the partial SOI substrate 350 shown in FIG. 18. The p⁺ plug region 119 of the semiconductor device of Embodiment 2 can be formed by a method shown in the specification of U.S. Pat. No. 5,869,875, and C. S. Kim, J. Park, H. K. Yu, “Trenched Sinker LDMOSFET (TS-LDMOS) Structure for High Power Amplifier Application Above 2 GHz”, IEDM Tech. Dig. December 2001, pp. 887-890. The p⁺ body contact region 114 in the semiconductor device of Embodiment 3 can be formed by changing the thickness of the diffusion of phosphorus ions of the p⁺ body contact region 114 in the fabrication of the semiconductor device according to Embodiment 1.

### Embodiment 4

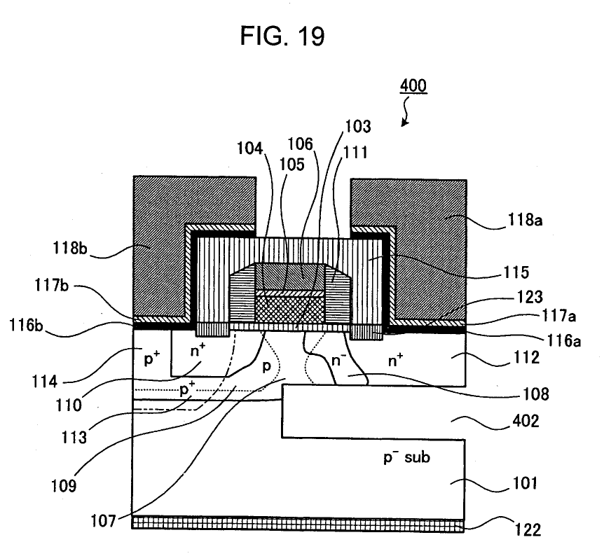

FIG. 19 is a diagram depicting a configuration of a semiconductor device according to Embodiment 4. Aspects that are different from the semiconductor device 100 of Embodiment 1 will be described for the configuration of the semiconductor device 400 shown in FIG. 19. In the semiconductor device 400, a Silicon-On-Nothing (SON) layer 402, instead of the BOX region 102 formed of silicon dioxide in Embodiment 1, is formed in the p⁻ substrate 101. By the SON layer 402, a thermal path from the region where heat is generated to the p⁻ substrate 101 can be decreased so that thermal dissipation of the device is improved.

The SON layer 402 has low effective dielectric constant εr (εr≅1), so thickness is about ¼ of the insulation film (buried oxide region) having a same electrostatic capacity. For example, a 0.4 μm thick SON has an electrostatic capacity which is equivalent to a 1.6 μm thick insulation film. Therefore in the semiconductor device 400, the thickness of the SON layer 402 can be 150 nm (1500 Å) or more, and thickness can be decreased compared with the case of forming the BOX region 102 by silicon dioxide (Embodiment 1 to Embodiment 3). The thickness of the region on the insulation film using Tₛᵢ is 150 to 300 nm (1500 Å to 3000 Å), just like Embodiment 1.

Fabrication Method for Semiconductor Device 400

An example of the fabrication method for the semiconductor device 400 will now be described. The fabrication method for the semiconductor device 400, however, is not limited to the process described herein below.

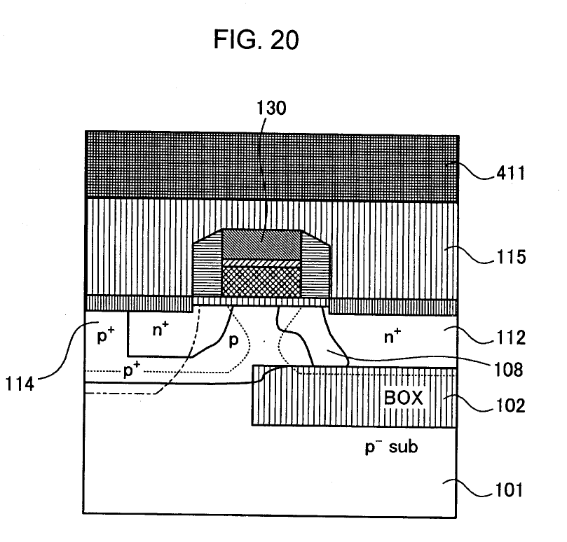

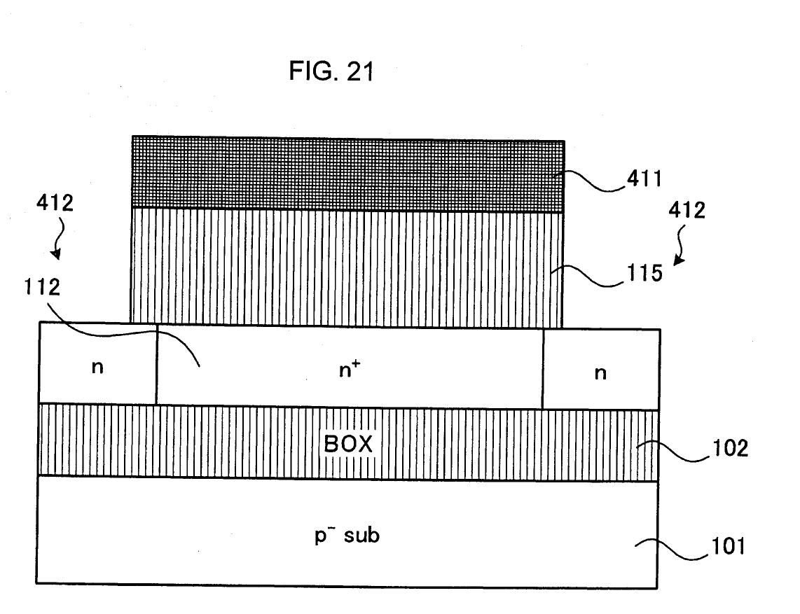

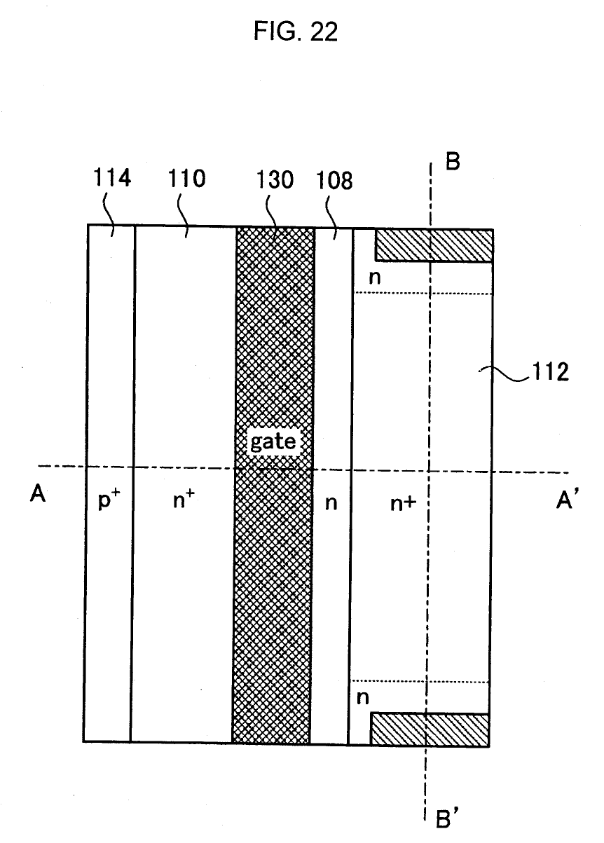

FIG. 20 to FIG. 30 are diagrams depicting the fabrication of the semiconductor device according to Embodiment 4. First the same processes as the fabrication method for the semiconductor device 100 of Embodiment 1 shown in FIG. 2 to FIG. 15 are performed. As FIG. 15 shows, the inter-layer insulation film 115 is deposited on the entire surface of the partial SOI substrate 150, then the photolithography and anisotropic etching (e.g. RIE) are performed, as shown in FIG. 20 and FIG. 21, and forms an opening portion 412 that reaches a region on the insulation film. FIG. 20 is a cross-sectional view at the A-A′ line in the layout diagram of the semiconductor device shown in FIG. 22. FIG. 21 is a cross-sectional view sectioned at the B-B′ line in the layout diagram of the semiconductor device shown in FIG. 22. Then the photo resist 411 is removed.

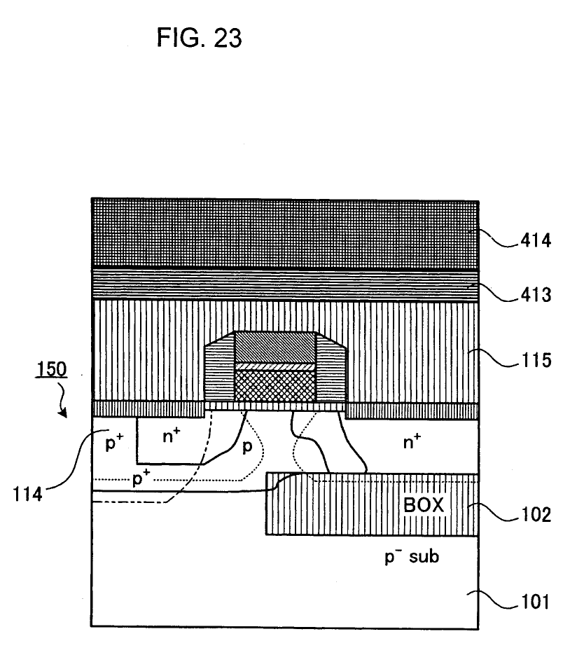

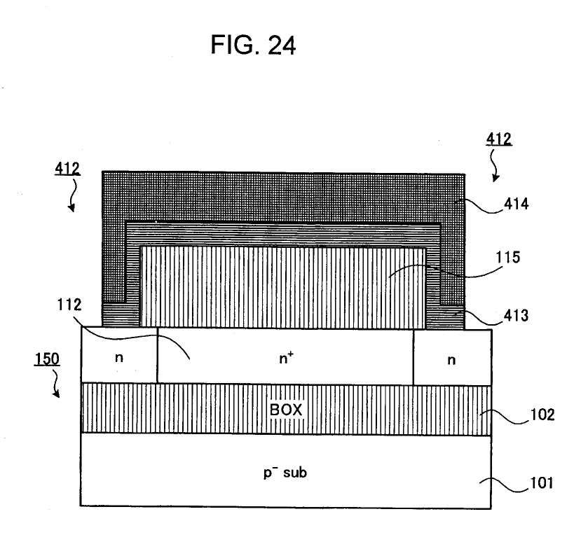

Then as FIG. 23 and FIG. 24 show, a 0.1 to 0.3 μm thick silicon nitride film 413 is deposited on the entire surface of the partial SOI substrate 150. Then a part of the silicon nitride film 413, deposited on the opening portion 412, is removed by photolithography. FIG. 23 is a cross-sectional view sectioned at the A-A′ line in the layout diagram of the semiconductor device shown in FIG. 22. FIG. 24 is a cross-sectional view sectioned at the B-B′ line in the layout diagram of the semiconductor device shown in FIG. 22. Then the photo resist 414 is removed.

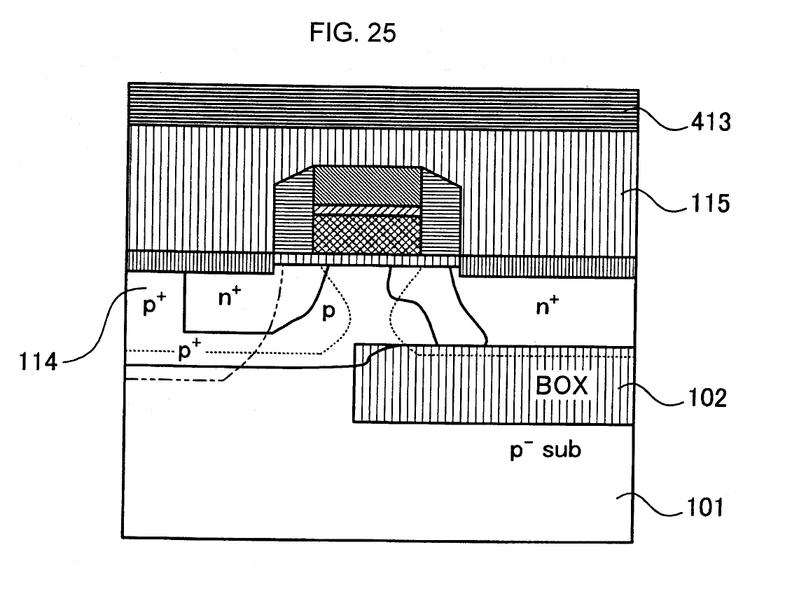

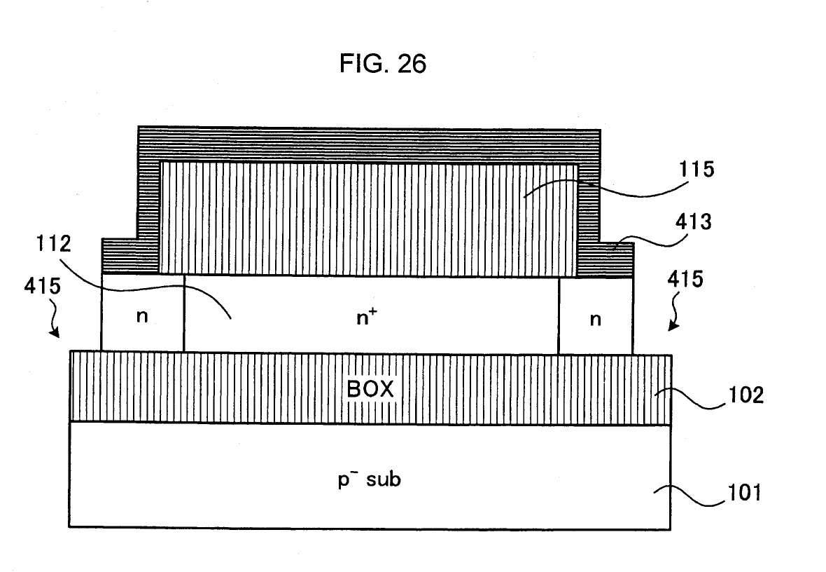

Then as FIG. 25 and FIG. 26 show, anisotropic etching is performed using a silicon nitride film 413 as a mask, so that a part of the region on the insulation layer is removed until it reaches the BOX region 102. A trench 415 is formed on the region on the insulation layer. FIG. 25 is a cross-sectional view sectioned at the A-A′ line in the layout diagram of the semiconductor device shown in FIG. 22. FIG. 26 is a cross-sectional view sectioned at the B-B′ line in the layout diagram of the semiconductor device shown in FIG. 22.

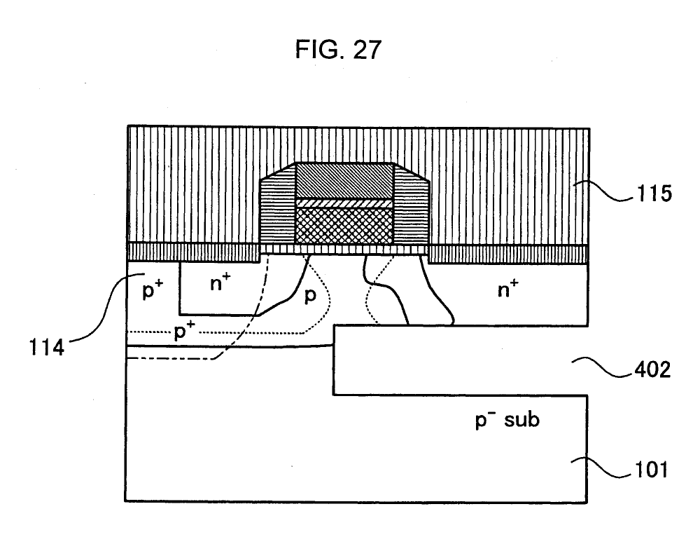

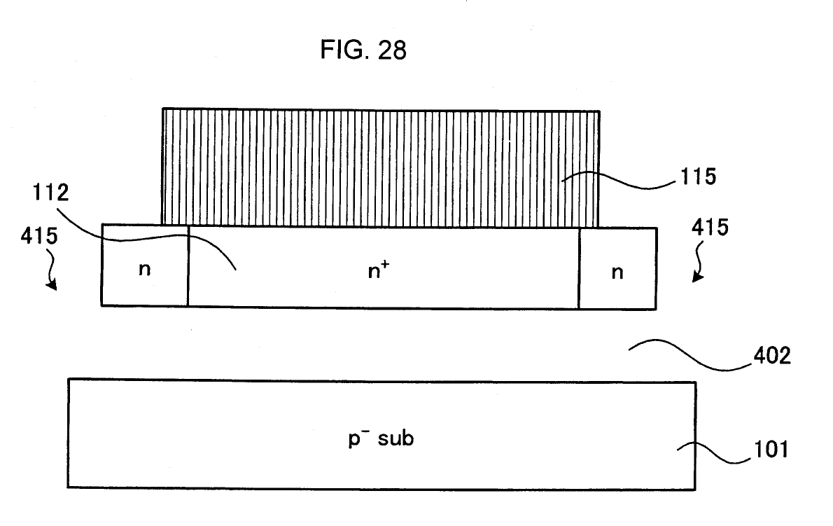

Then the silicon dioxide, which is the BOX region 102, is removed by wet etching, and the SON layer 402 is formed, as shown in FIG. 27 and FIG. 28. Then the silicon nitride film 413 is removed. FIG. 27 is a cross-sectional view sectioned at the A-A′ line in the layout diagram of the semiconductor device shown in FIG. 22. FIG. 28 is a cross-sectional view sectioned at the B-B′ line in the layout diagram of the semiconductor device shown in FIG. 22.

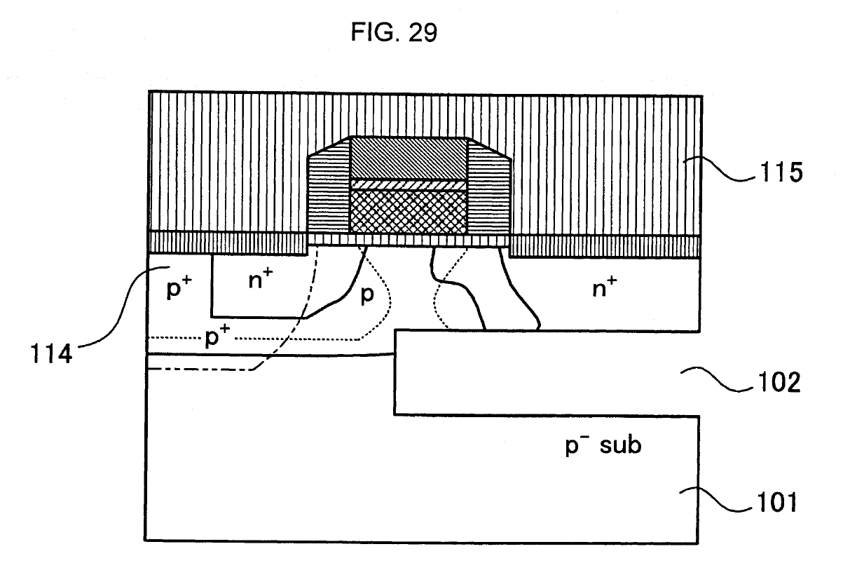

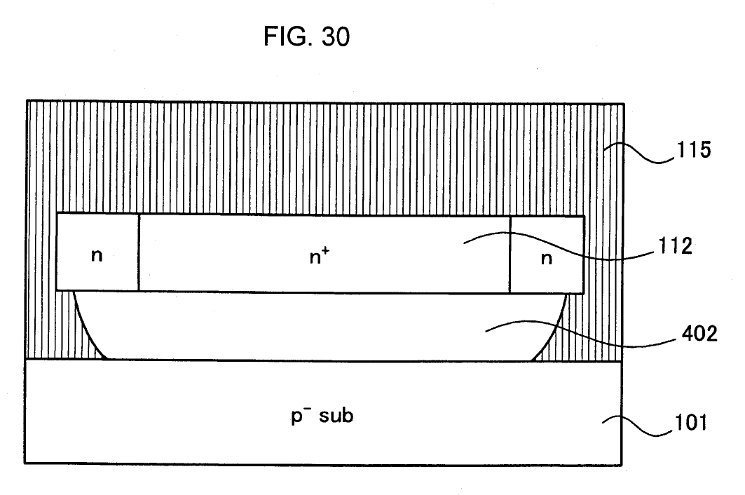

Then as FIG. 29 and FIG. 30 show, a silicon oxide film (inter-layer insulation film 115) is deposited so as to fill the trench 415 shown in FIG. 28, and the surface of the device is planarized. FIG. 29 is a cross-sectional view sectioned at the A-A′ line in the layout diagram of the semiconductor device in FIG. 22. FIG. 30 is a cross-sectional view sectioned at the B-B′ line in the layout diagram of the semiconductor device in FIG. 22.

Then a contact is formed by photolithography and etching, and a contact protective layer (e.g. titanium (Ti), titanium nitride (TiN)) is deposited on the entire surface of the partial SOI substrate 150, and an aluminum (Al) interconnect layer containing silicon (Si) and copper (Cu) components is deposited thereon. Then a first metal layer is formed by photolithography and etching. Then a multi-layer process is performed if necessary, and silicide layers 116a, 116b, barrier layers 117a, 117b, drain electrode 118a and source electrode 118b are formed. Also a rear face electrode 122 is formed. By the above processes, the semiconductor device 400 according to Embodiment 4 shown in FIG. 19 can be fabricated.

This semiconductor device 400 is suitable for an integrated type device. For example, if the width of the extended drain region 108 is 0.3 μm, a device of which breakdown voltage is about 16V is obtained. This device is suitable for a power amplification device of a mobile radio communication terminal of which power supply is one cell Li ion/polymer battery (3.6V), for example.

Characteristics of Semiconductor Device 400

The characteristics of the semiconductor device 400 will now be described. Here the characteristics of a device having a SON layer 402, such as the semiconductor device 400 shown in FIG. 19, and the characteristics of a device having a BOX region, such as the semiconductor device 100 of Embodiment 1 (see FIG. 1), are compared. First the relationship of the thickness (size in depth direction) T_{BOX} of the BOX region 102 or the SON layer 402 of the semiconductor device and the maximum oscillation frequency (frequency at which the power gain of the semiconductor device becomes 1) fₘₐₓ will be described.

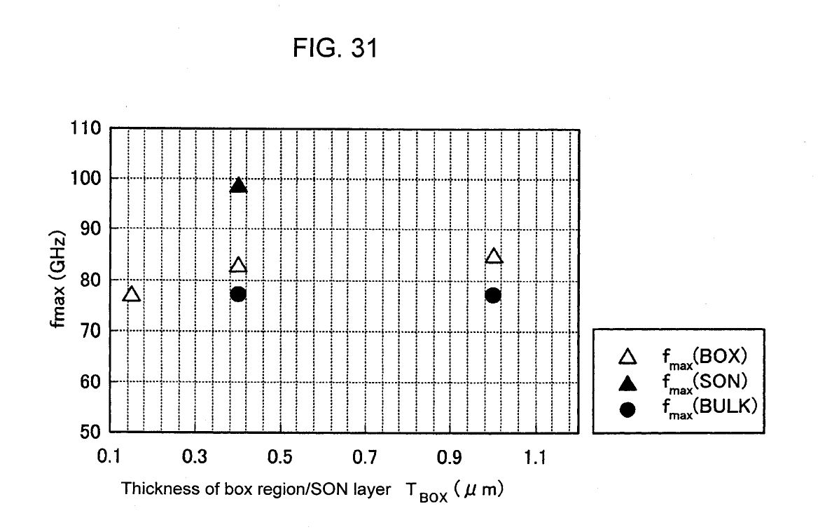

FIG. 31 is a graph depicting the relationship between the thickness of the BOX region or the SON layer and the maximum oscillation frequency. In FIG. 31, the ordinate indicates the maximum oscillation frequency fₘₐₓ (GHz), and the abscissa indicates the thickness T_{BOX} of the BOX region 102 or the SON layer 402. In FIG. 31, dimensions other than the thickness of the BOX region 102 or SON layer 402 of the device are: thickness of the gate insulation film 103 is 10 nm, width of the extended drain region 108 is 0.3 μm, and width of the p body region 107 is 0.5 μm. The gate structure portion 130 of the semiconductor device is made of metal.

In FIG. 31, a white triangle (Δ) indicates a maximum oscillation frequency (fₘₐₓ (BOX)) of the device where the BOX region 102 is formed, and a black filled triangle (▴) indicates a maximum oscillation frequency (fₘₐₓ (SON)) of the device where the SON layer 402 is formed. In FIG. 31, a black filled circle () indicates a maximum oscillation frequency (fₘₐₓ (BULK)) of a silicon bulk device having a conventional structure which has no BOX region 102 or SON layer 402, and is constant regardless the value on the abscissa.

As FIG. 31 shows, the maximum oscillation frequency fₘₐₓ of the semiconductor device 400, where the 0.4 μm thick SON layer 402 is formed, is much higher than the maximum oscillation frequency fₘₐₓ of the semiconductor device 100, where the 1 μm thick BOX region 102 is formed. Hence the device where the SON layer 402 is formed can exhibit good device characteristics even if the SON layer 402 is thin, compared with the device where the BOX region 102 is formed.

Now the relationship of the thickness (size of the depth direction) T_{BOX} of the BOX region 102 or SON layer 402 of the semiconductor device and the cut-off frequency fₜ, and the relationship of the thickness T_{BOX} of the BOX region 102 or SON layer 402 of the semiconductor device and the maximum oscillation frequency fₘₐₓ will be described.

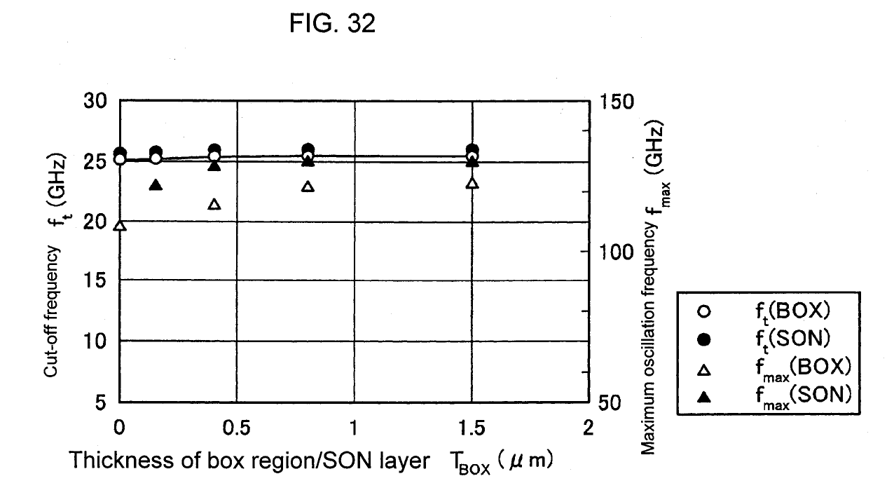

FIG. 32 is a graph depicting the relationship of the thickness of the BOX region or SON layer and the peak value of the cut-off frequency, and the relationship of the thickness of the BOX region or SON layer and the maximum oscillation frequency. In FIG. 32, the left ordinate indicates the cut-off frequency fₜ (GHz), the right ordinate indicates the maximum oscillation frequency fₘₐₓ (GHz), and the abscissa indicates the thickness T_{BOX} of the BOX region 102 or SON layer 402. The plot where the value of the abscissa is 0 indicates the characteristic value of the silicon bulk device with a conventional structure, which has no BOX region 102 or SON layer 402.

In FIG. 32, dimensions other than the thickness of the BOX region 102 or the SON layer 402 of the device are: the thickness of the gate insulation film 103 is 10 nm, width of the gate structure portion 130 is 0.4 μm, width of the extended drain region 108 is 0.3 μm, and width of the p body region 107 is 0.4 μm. The position at the source side edge of the BOX region 102 or SON layer 402 matches with the vertical line Lc dropped from the center of the gate structure portion 130 (see FIG. 1). The substrate resistivity of the device is 10 Ω* cm. The breakdown voltage, when the current density between source and drain in OFF status (V_{GS}=0) is 100 pA/μm, is about 14V.

In FIG. 32, a white circle (◯) indicates a cut-off frequency (fₜ (BOX)) of the device where the BOX region 102 is formed, and a black filled circle () indicates a cut-off frequency (fₜ (SON)) of the device where the SON layer 402 is formed. A white triangle (Δ) indicates a maximum oscillation frequency (fₘₐₓ (BOX)) of the device where the BOX region 102 is formed, and a black filled triangle (▴) indicates a maximum oscillation frequency (fₘₐₓ (SON)) of the device where the SON layer 402 is formed.

As FIG. 32 shows, the device characteristics are better in the device where the BOX region 102 or SON layer 402 is formed than the device having a conventional structure (plotted at the value 0 in the abscissa). And the device characteristics are better in the device having the SON layer 402 than the device having the BOX region 102.

As described above, in the semiconductor device 400 of Embodiment 4, the SON layer 402 is formed instead of the BOX region 102 formed of silicon dioxide. According to the semiconductor device 400, good device characteristics can be implemented even if the SON layer 402 is formed thinner than the BOX region 102 formed of silicon dioxide.

### Embodiment 5

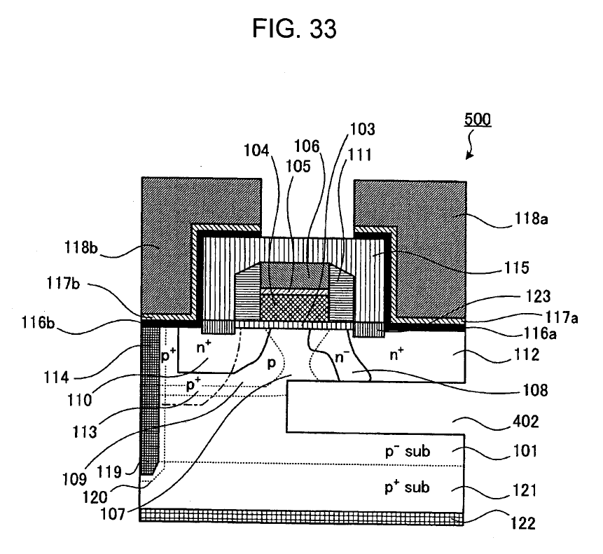

FIG. 33 is a diagram depicting a configuration of a semiconductor device according to Embodiment 5. Aspects that are different from the semiconductor device 400 of Embodiment 4 will be described for the configuration of the semiconductor device 500 shown in FIG. 33. In the semiconductor device 500, a p⁻ region (p⁻ substrate) 101 having high resistivity is formed on a p⁺ substrate 121 having low resistivity, and a SON layer 402 is formed on a part of the surface layer of the p⁻ region 101.

A p⁺ plug region 119 made of low resistivity polysilicon is formed in a trench which reaches from the surface of the p⁺ body contact region 114 to the p⁺ substrate 121. A p⁺ diffusion region 120 is formed around the trench where the p⁺ plug region 119 is formed by the diffusion of purities from the p⁺ plug region 119. This semiconductor device 500 is suitable for a discrete device, for example.

### Embodiment 6

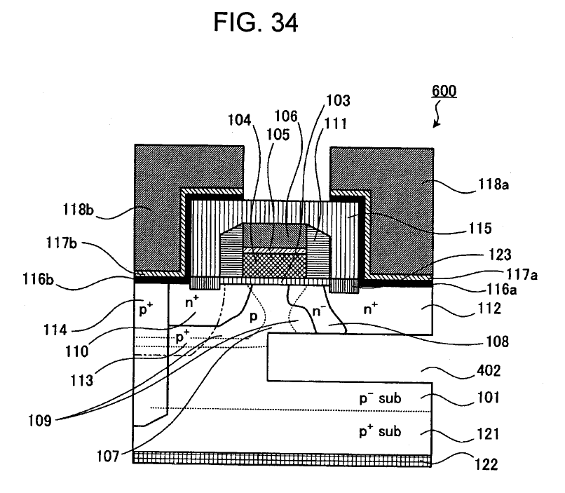

FIG. 34 is a diagram depicting a configuration of a semiconductor device according to Embodiment 6. Aspects that are different from the semiconductor device 400 of Embodiment 4 will be described for the configuration of the semiconductor device 600 shown in FIG. 34. In the semiconductor device 600, a p⁻ region (p⁻ substrate) 101 having high resistivity is formed on a p⁺ substrate 121 having low resistivity, just like the semiconductor device 500 of Embodiment 5, and a SON layer 402 is formed on a part of the surface layer of the p⁻ region 101.

In the semiconductor device 600, a p⁺ body contact region 114 penetrates through the p⁻ region 101, and reaches the p⁺ substrate 121. This semiconductor device 600 is suitable for a discrete device, for example.

To fabricate the semiconductor device according to Embodiment 5 or Embodiment 6, the partial SOI substrate 350 shown in FIG. 18 is used, instead of the partial SOI substrate 150 shown in FIG. 2, just like Embodiment 2 or Embodiment 3. In order to fabricate the semiconductor device according to Embodiment 5 or Embodiment 6, the processings shown in FIG. 3 to FIG. 15 or FIG. 20 to FIG. 30 are performed on the partial SOI substrate 350 shown in FIG. 18. The p⁺ plug region 119 of the semiconductor device of Embodiment 5 is formed by a method shown in the above mentioned Liang et al and Rotella. The p⁺ body contact region 114 of the semiconductor device of Embodiment 6 can be formed by changing the thickness of the diffusion of phosphorus ions of the p⁺ body contact region 114 in the fabrication of the semiconductor device of Embodiment 1.

In the semiconductor devices of Embodiment 4 to Embodiment 6, if the width of the extended drain region 108 is 0.3 μm, the dosage of phosphorus in FIG. 6 is 3×10¹² to 5×10¹² cm⁻², the threshold when the channel current density is 1×10⁻¹¹ A/μm is 0.5V, and the length of the gate structure 130 is 0.5 μm, then the breakdown voltage of the device is 15V or more.

### Embodiment 7

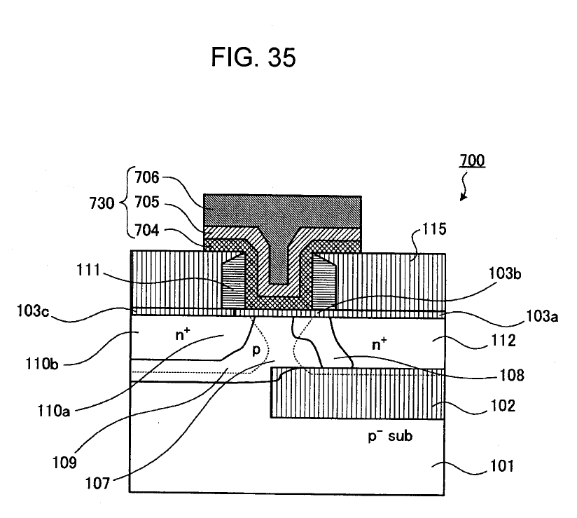

FIG. 35 is a diagram depicting a configuration of a semiconductor device according to Embodiment 7. Just like the semiconductor device 100 of Embodiment 1, the semiconductor device 700 shown in FIG. 35 comprises a p⁻ substrate 101, BOX region 102, p body region 107, extended drain region 108, p buried region 109, n⁺ source regions 110a and 110b, and n⁺ drain region 112.

The surface of the p body region 107 is covered with a gate insulation film 103b. Gate insulation films 103a and 103c are formed at the drain side and the source side of the gate insulation film 103b respectively. A low density polysilicon portion 704, a barrier film 705 which is formed of titanium nitride (TiN), and a T-shaped gate structure portion 730 comprising a metal gate portion 706 are formed on the gate insulation film 103b. A gate side wall spacer 111, which is a nitride film or an oxide film, is formed on the side face of the T-shaped gate structure portion 730. An inter-layer insulation film is formed 115 so as to cover the gate insulation films 103a and 103c and the gate side wall spacer 111.

In the semiconductor device 700 according to Embodiment 7, each composing element on the substrate is formed using a dummy gate structure portion as a mask. This is for preventing a drop in reliability of the gate insulation film caused by high temperature diffusion. More specifically, after forming each composing element on the substrate using the dummy gate structure portion as a mask, the dummy gate structure portion is removed. Then the gate insulation film is formed again, and a metal T-shaped gate structure 730 is formed. By this, a semiconductor device of which reliability of the gate insulation film is high and resistivity of the gate electrode is low can be fabricated.

A channel density distribution can be formed having an inclination that is aligned with the dummy gate structure portion, so operation can be faster compared with a device having a conventional structure, where channel density distribution is uniform. Moreover, the modulation of channel length can be suppressed even more, so this semiconductor device can be applied to a high-speed device.

Fabrication Method for Semiconductor Device 700

An example of the fabrication method for the semiconductor device 700 will be described. The fabrication method for the semiconductor device 700, however, is not limited to the process described herein below.

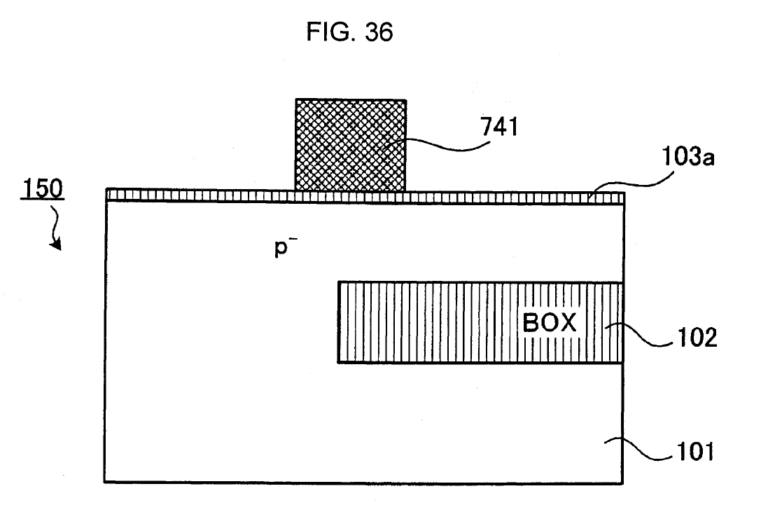

FIG. 36 to FIG. 46 are diagrams depicting the fabrication of the semiconductor device according to Embodiment 7. In the following description, a case of using the partial SOI substrate 150 shown in FIG. 2 for fabrication of the semiconductor device 700 is described, but the partial SOI substrate 350 shown in FIG. 18 may be used for fabrication of the semiconductor device 700. In this case, the p⁻ substrate 101 portion, out of the configuration of the semiconductor device 700 shown in FIG. 35, has a configuration where the p⁻ region (p⁻ substrate) 101 having high resistivity is formed on the p⁺ substrate 121 having low resistivity (see FIG. 18).

First, as FIG. 36 shows, the gate insulation film 103a is formed on the partial SOI substrate 150. Then the dummy gate structure portion 741 is formed on a part of the surface of the gate insulation film. At this time, the dummy gate structure portion 741 is positioned above the edges of the BOX region 102 in the width direction. The dummy gate structure portion 741 is formed by polysilicon in which impurities are not included or the impurity density is low.

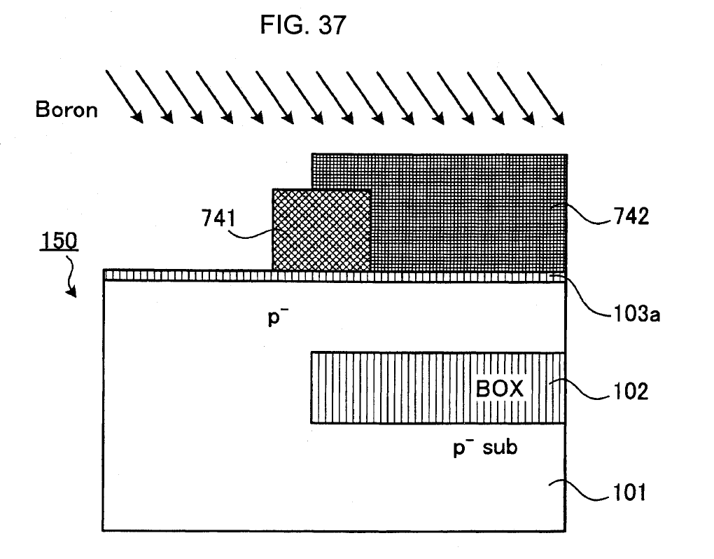

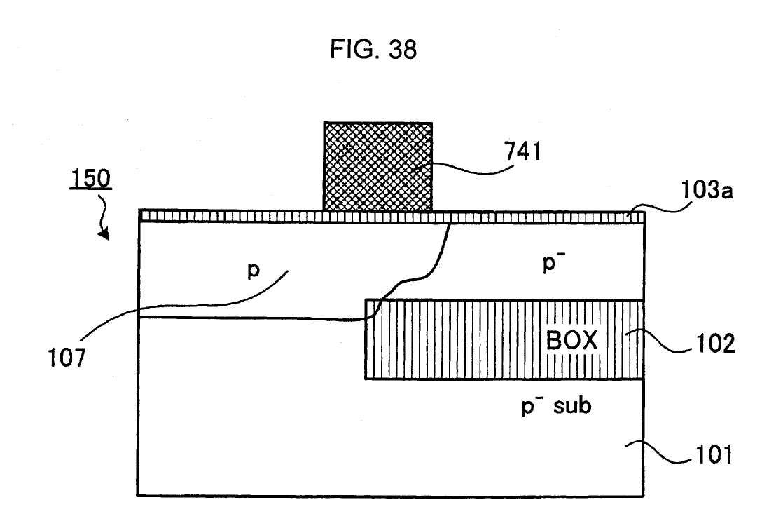

Then as FIG. 37 shows, the surface of the dummy gate structure portion 741 at the drain side and the surface of the partial SOI substrate 150 at the drain side are covered with photo resist 742 by photolithography. Then boron (B) ions are implanted diagonally (e.g. 45° angle into the surface of the partial SOI substrate 150) from the source side so as to self-align with the dummy gate structure portion 741. After removing the photo resist 742, thermal diffusion is performed, and the p body region 107 is formed as shown in FIG. 38.

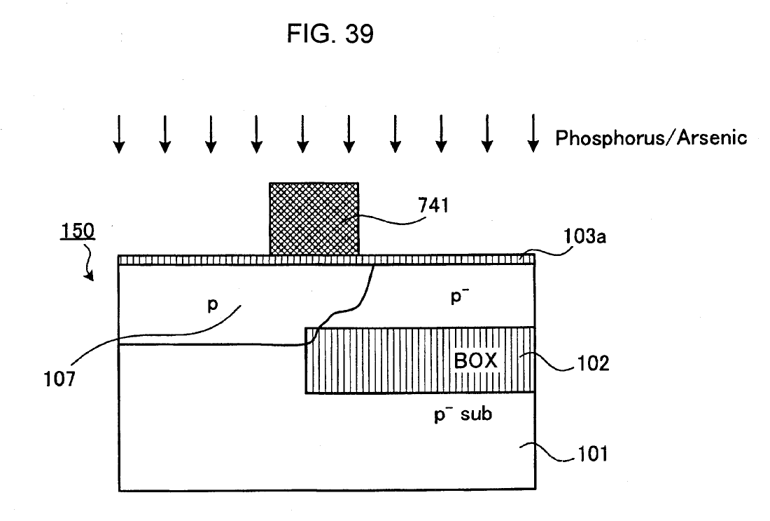

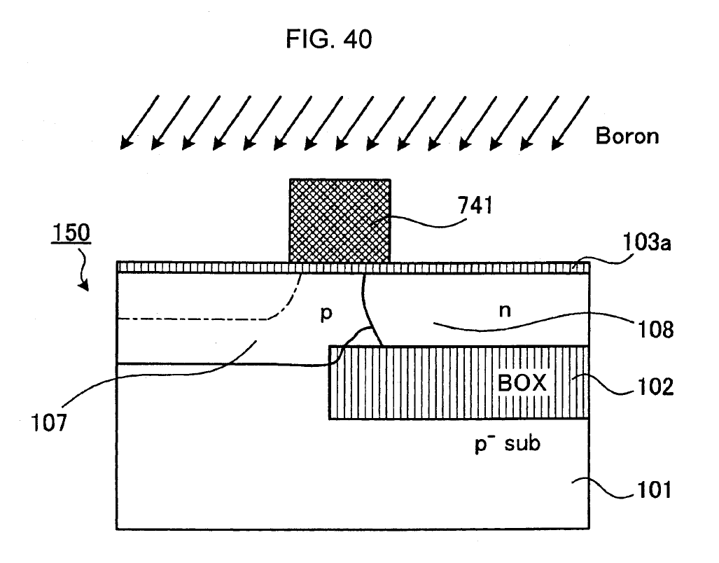

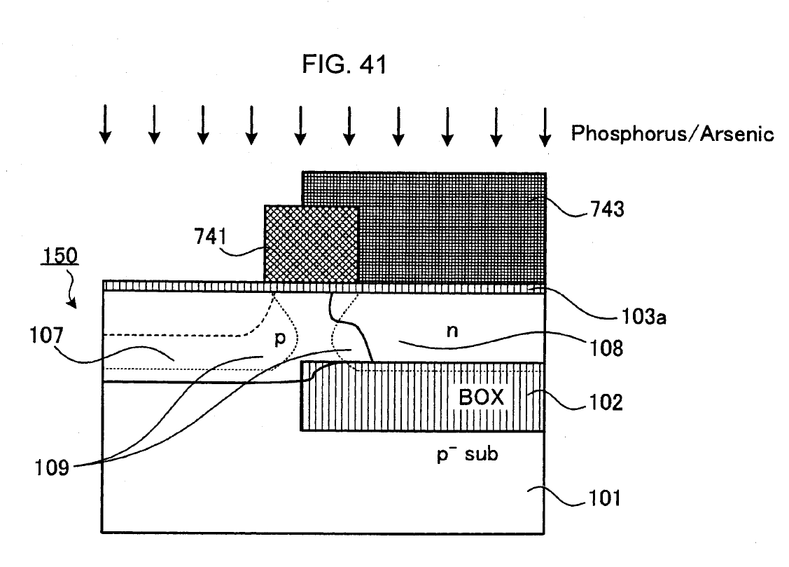

Then as FIG. 39 shows, phosphorus (P) ions or arsenic (As) ions are implanted vertically into the surface of the partial SOI substrate 150, so as to align with the dummy gate structure portion 741, and the extended drain region 108 is formed (see FIG. 40). Then as FIG. 40 shows, boron (B) ions are implanted diagonally from the drain side so as to align with the dummy gate structure portion 741. Then diffusion is performed to form the p buried region 109 (see FIG. 41).

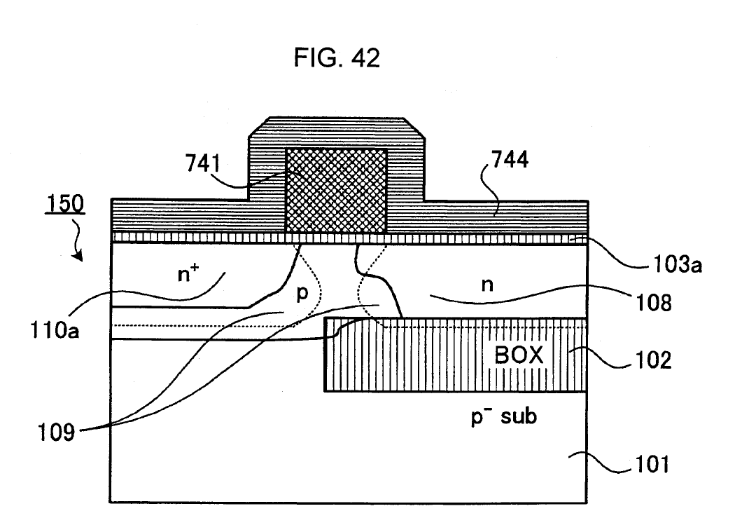

Then as FIG. 41 shows, the surface of the dummy gate structure portion 741 at the drain side and the surface of the partial SOI substrate 150 where the extended drain region 108 is formed are covered with photo resist 743 by photolithography. Then phosphorus (P) or arsenic (As) ions are implanted vertically into the surface of the partial SOI substrate 150. The photo resist 743 is removed, and implanted ions are activated to form the n⁺ source region 110a (see FIG. 42).

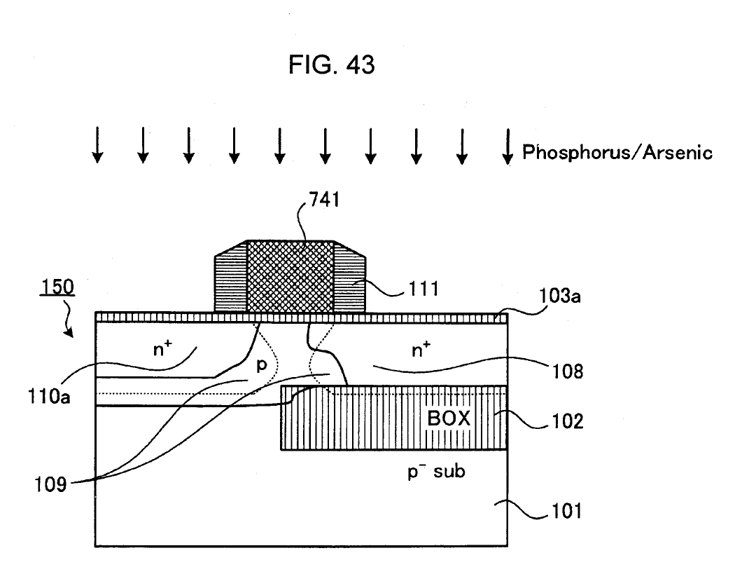

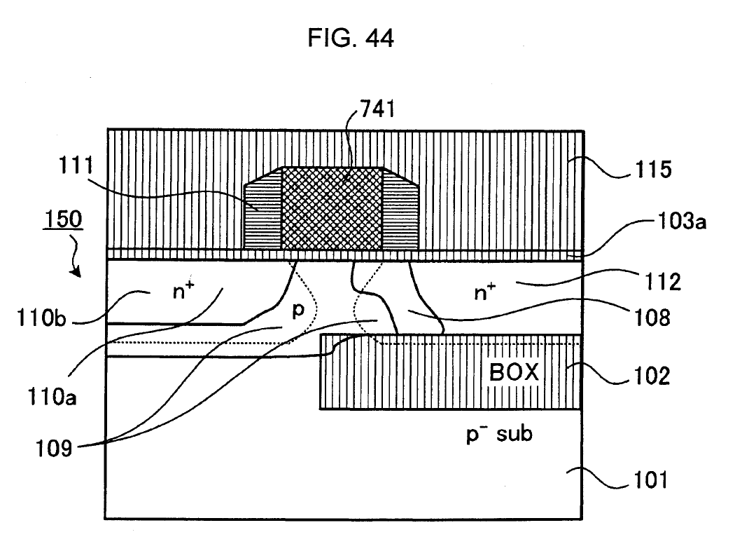

Then, as FIG. 42 shows, a silicon nitride (Si₃N₄) film 744 is deposited on the entire surface of the partial SOI substrate 150. Then anisotropic etching is performed on this silicon nitride film 744, and the gate side wall spacer 111 is formed (see FIG. 43). Then as FIG. 43 shows, phosphorus (P) or arsenic (As) ions are implanted vertically into the surface of the partial SOI substrate 150 so as to align with the gate side wall spacer 111, and the n⁺ drain region 112 and the n⁺ source region 110b are formed (see FIG. 44).

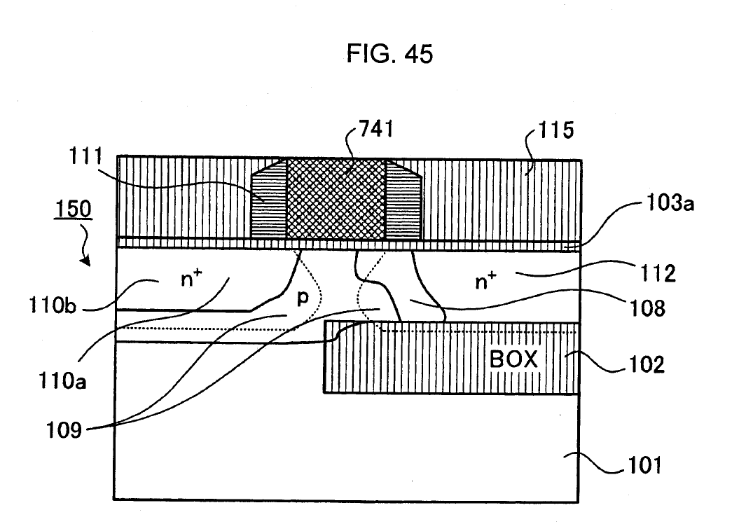

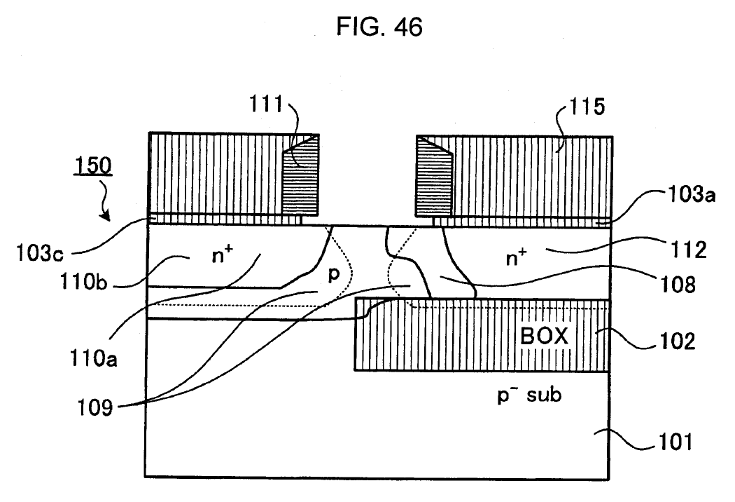

Then, as FIG. 44 shows, an inter-layer insulation film 115 is deposited on the entire surface of the partial SOI substrate 150 so as to be thicker than the dummy gate structure portion 741. Then the inter-layer insulation film 115 is polished by CMP (Chemical Mechanical Polishing), so that the dummy gate structure portion 741 is exposed from the surface of the inter-layer insulation film 115, as shown in FIG. 45. Then, as FIG. 46 shows, the dummy gate structure portion 741 is removed by selective etching. Next, the gate insulation film 103a, directly under the dummy gate structure portion 741 and at a part of the periphery thereof, is removed by wet etching. Of the remaining gate insulation film, the portion remaining at the source side is the gate insulation films indicated by symbols 103a and 103c in FIG. 35.

Then the gate insulation film 103b is formed by thermal oxidation in a portion where the gate insulation film 103a is removed (see FIG. 35). Then a low density polysilicon film to be the polysilicon portion 704 is deposited on the entire surface of the partial SOI substrate 150. A titanium nitride (TiN) film to be a barrier film 705 is deposited on the surface of the polysilicon film at about several tens of nm. A metal gate material to be a metal gate portion 706 is deposited on the surface or the titanium nitride film. Then the region to be a T-shaped gate is masked by photolithography, and the T-shaped gate structure portion 730 is formed by anisotropic etching. By the above processes, the semiconductor device 700 according to Embodiment 7 shown in FIG. 35 can be fabricated.

As described above, in the semiconductor device 700 according to Embodiment 7, each composing element on the substrate is formed using the dummy gate structure portion 741 as a mask. By this, a semiconductor device of which reliability of the gate insulation film is high and resistivity of the gate electrode is low can be fabricated. Also the channel density distribution, having a slope aligned with the dummy gate structure portion 741, is formed, so operation is faster compared with the device having a conventional configuration, where the channel density distribution is uniform. Moreover, modulation of the channel length can be suppressed even more, so this semiconductor device can be applied to a high-speed device.

### CHARACTERISTICS OF PRESENT INVENTION

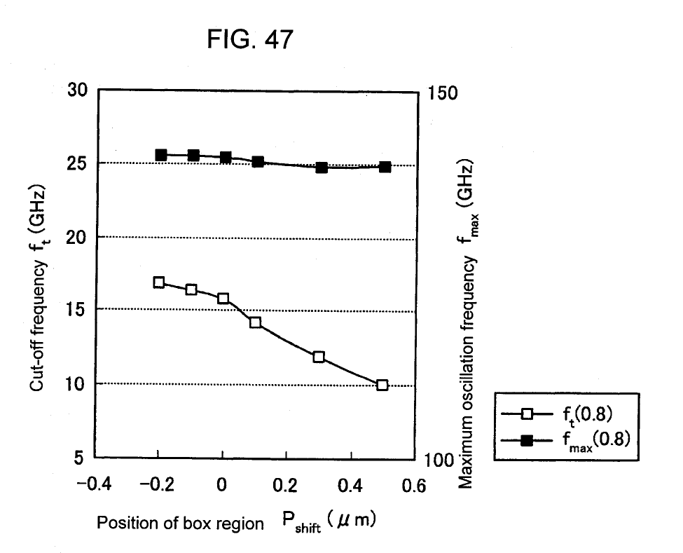

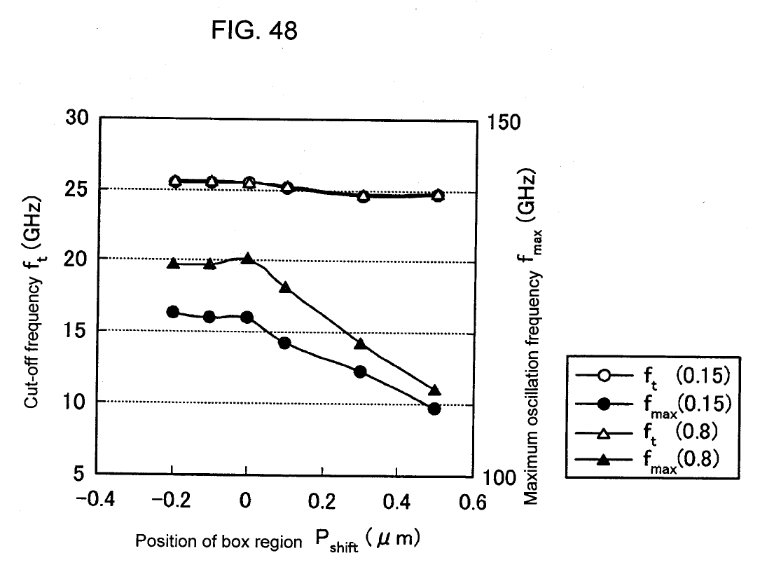

Now the characteristics of the semiconductor devices of the present invention will be described. First, a relationship of the position of the source side edge of the BOX region 102 or the SON layer formed instead of the BOX region 102 (distance P_{shift} from the center of the gate structure portion 730) and cut-off frequency fₜ, and a relationship of the source side edge position of the BOX region 102 or the SON layer and the maximum oscillation frequency fₘₐₓ, will be described. FIG. 47 is a graph depicting the relationship of a source side edge position of the BOX region in a device where the BOX region is formed and a peak value of the cut-off frequency, and the relationship of a source side edge position of the BOX region and the maximum oscillation frequency. FIG. 48 is a graph depicting the relationship of a source side edge position of the SON layer in a device where the SON layer is formed, and a peak value of the cut-off frequency, and the relationship of the source side edge position of the SON layer and the maximum oscillation frequency.

In FIG. 47 and FIG. 48, the left ordinate indicates the cut-off frequency ft (GHz), the right ordinate indicates the maximum oscillation frequency fₘₐₓ (GHz), and the abscissa indicates a distance P_{shift} (μm) between the source side edge of the BOX region 102 or the SON layer and a vertical line L_{C} dropped from the center of the gate structure portion 730 in the length direction (see FIG. 1). P_{shift}=0 means that the edge of the BOX region 102 or the SON layer matches with the position L_{C} of the vertical line dropped from the center of the gate structure portion 730 (see FIG. 1). P_{shift}>0 means that the edge of the BOX region 102 or the SON layer is at the drain side of the vertical line Lc dropped from the center of the gate structure portion 730. P_{shift}<0 means that the edge of the BOX region 102 or the SON layer is at the source side of the vertical line Lc dropped from the center of the gate structure portion 730.

In FIG. 47 and FIG. 48, dimensions of the device are: thickness of the gate insulation film 103b is 10 nm, length of the gate structure portion 730 is 0.4 μm, and width of the extended drain region 108 is 0.3 μm. In other words, in FIG. 47 and FIG. 48, the plot in P_{shift}>0.2 μm, indicates the characteristic values of the semiconductor device with a conventional structure (BOX region is not formed up to a position overlapping the gate structure portion 730), where dimensions, other than the source side edge position of the BOX region 102 or the SON layer 402, are the same as the semiconductor device 100.

In FIG. 47 and FIG. 48, the substrate resistivity of the device is 10 Ω·cm. The breakdown voltage is about 14V when the current density between source and drain is 100 pA/μm in an OFF status (V_{GS}=0). In FIG. 47, a white square (□) indicates a cut-off frequency fₜ (0.8) when the thickness of the BOX region 102 is 0.8 μm, and a black filled square (▪) indicates a maximum oscillation frequency fₘₐₓ (0.8) when the thickness of the BOX region 102 is 0.8 μm.

In FIG. 48, a white circle (◯) indicates a cut-off frequency fₜ (0.15) when the thickness of the SON layer is 0.15 μm, and a black filled circle () indicates a maximum oscillation frequency fₘₐₓ (0.15) when the thickness of the SON layer is 0.15 μm, a white triangle (Δ) indicates a cut-off frequency fₜ (0.8) when the thickness of the SON layer is 0.8 μm, and a black filled triangle (▴) indicates a maximum oscillation frequency fₘₐₓ (0.8) when the thickness of the SON layer is 0.8 μm.

In both cases of FIG. 47 and FIG. 48, the respective characteristic values drop in the P_{shift}>0 area, with P_{shift}=0 at the border, from which the cut-off frequency characteristics and the maximum oscillation frequency characteristics deteriorate. In other words, compared with a device of a conventional structure, the cut-off frequency and the maximum oscillation frequency are higher, and device characteristics are better in the device according to the present invention.

Because of this, a configuration where the BOX layer or the SON layer extends to a position overlapping the gate electrode can implement a higher cut-off frequency and maximum oscillation frequency, and can implement better device characteristics compared with a configuration where the BOX layer or the SON layer does not extend to a position overlapping the gate electrode, as in the case of a conventional structure. This is also true in Embodiment 1, for example, where no spacer region 111, p⁺ buried region 113, p buried region 109 and silicide region 123 exist.

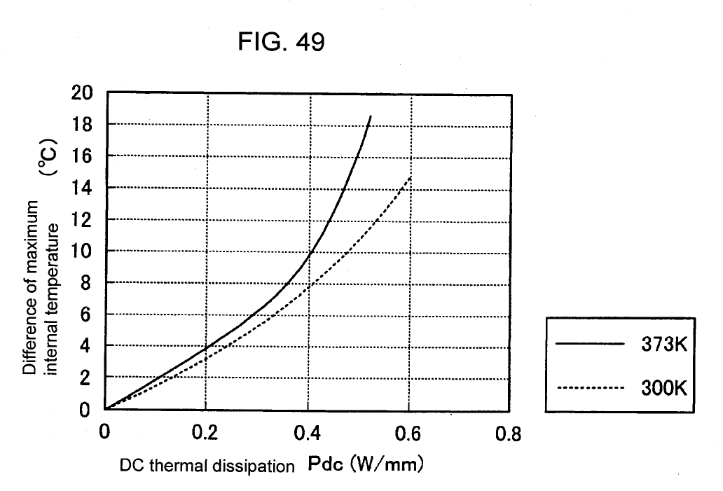

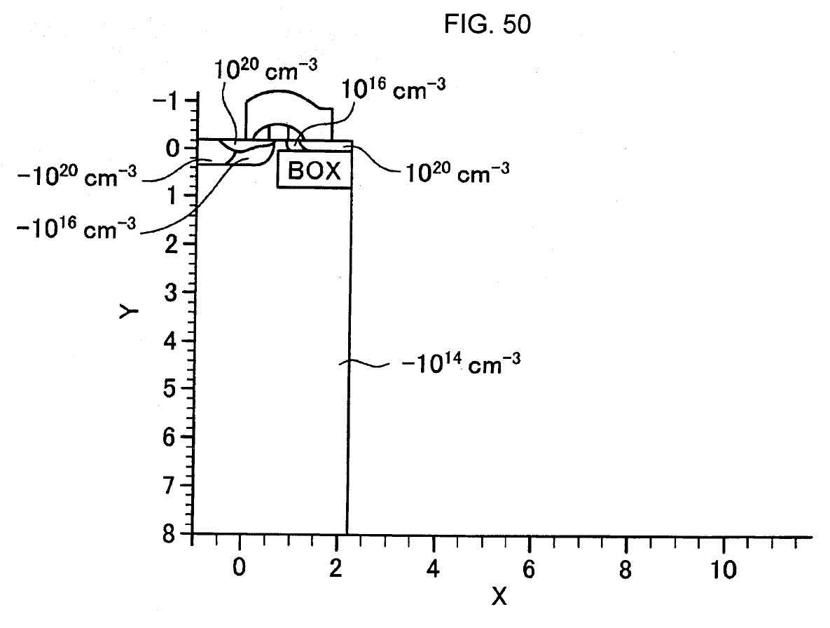

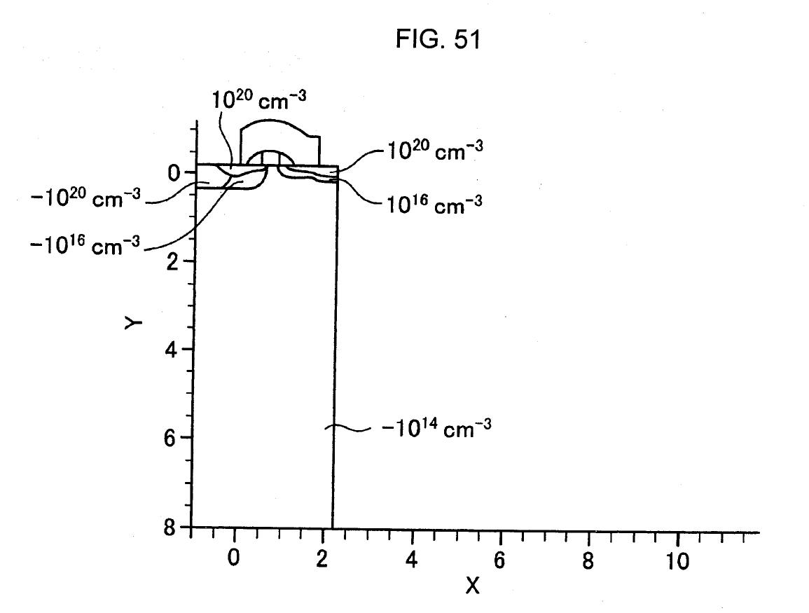

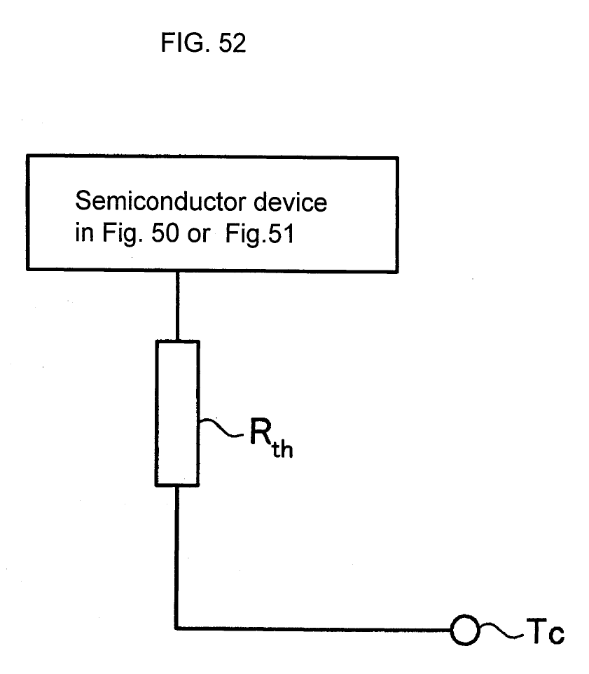

Now the maximum internal temperature of the semiconductor device according to the present invention (semiconductor device where a BOX region 102 is formed) and the semiconductor device according to the prior art (semiconductor device where a silicon bulk substrate is used) will be described. FIG. 49 is a graph depicting a simulation result of the maximum internal temperature of the semiconductor device of the present invention and the semiconductor device of the prior art. FIG. 49 shows the difference of the maximum internal temperatures when the semiconductor devices in FIG. 50 and FIG. 51 are connected to the thermal circuit in FIG. 52 respectively.

FIG. 50 is a diagram depicting an impurity density distribution of the semiconductor device of the present invention. FIG. 51 is a diagram depicting an impurity density distribution of the semiconductor device of the prior art. In the semiconductor devices shown in both FIG. 50 and FIG. 51, the length of the gate electrodes are 0.4 μm, and the thickness of the gate electrodes are 10 nm. In the semiconductor device of the present invention shown in FIG. 50, the thickness of the region on the insulation film is 180 nm, and the thickness of the BOX region 102 is 0.8 μm. In the semiconductor devices shown in FIG. 50 and FIG. 51, the surface of the substrate and the cross-sections at the left and right are insulated.

FIG. 52 is a diagram depicting a configuration of the thermal circuit used for simulation in FIG. 49. The semiconductor device shown in FIG. 50 or FIG. 51 is connected to a case via the thermal resistance Rₜₕ. The thermal resistance Rₜₕ is a thermal resistance of the silicon substrate, and the width is the same as the semiconductor devices shown in FIG. 50 and FIG. 51 (x direction), and the thickness is 250 μm.

In FIG. 49, the ordinate is a difference of the maximum internal temperatures (° C.) between the semiconductor device of the present invention shown in FIG. 50 and the semiconductor device of the prior art shown in FIG. 51, and the abscissa is a DC thermal dissipation Pdc (W/mm). The solid line in FIG. 49 indicates the temperature difference when the case temperature (temperature at the interface between the case and the silicon substrate) in the thermal circuit shown in FIG. 52 is 373K. The dotted line in FIG. 49 indicates the temperature difference when the case temperature is 300K.

As FIG. 49 shows, if the DC thermal dissipation Pdc is 0.4 W/mm, the difference of the maximum internal temperatures of the semiconductor device of the present invention and the semiconductor device of the prior art is 10° C. or less. In an actual device, thermal dissipation via metal interconnects from the substrate surface, and a three-dimensional thermal diffusion effect are generated. Therefore the difference of the maximum internal temperatures between the semiconductor device of the present invention and the semiconductor device of the prior art is even smaller. In this way, the semiconductor device of the present invention has a thermal dissipation equivalent to the semiconductor device of the prior art.

As described above, according to the semiconductor device of Embodiment 1 to Embodiment 7, the BOX region 102 or the SON layer is formed in an area from the drain region 112 to a position around the vertical line Lc dropped from the center of the gate structure portion 130, 730. Because of this, the extended drain region 108 and the p⁻ substrate 101 can be separated by the BOX region 102 or the SON layer 402, and the parasitic capacitance between the extended drain region 108 and the p⁻ substrate 101 can be decreased. Also the drain-induced barrier lowering effect can be suppressed, so the breakdown voltage of the device can be improved without two-dimensionally converging the electrostatic power lines of the extended drain region 108 into the p⁺ body contact region 114, as in the case of the silicon bulk device.

According to the semiconductor devices of Embodiment 1 to Embodiment 7, the p⁺ buried region 113 is formed under the n⁺ source region 110, so the parasitic bipolar transistor comprised of the n⁺ drain region, p⁻ substrate and n⁺ source region is hardly activated. Hence the semiconductor device 100 can also be applied to a high breakdown device, unlike the semiconductor device according to Japanese Patent Application Laid-Open No. S55-148464 (see FIG. 56).

In the semiconductor devices of Embodiment 1 to Embodiment 7, the thickness of the region on insulation film can be 150 to 300 nm (1500 to 3000 Å), and a high breakdown voltage can be obtained. If the BOX region 102 is formed of silicon dioxide, the parasitic capacitance between the extended drain region 108/drain region 112 and the p⁻ substrate 101 can be decreased by setting T_{BOX}≧400 nm (4000 Å).

As described above, the present invention is effective for a device for which a wide safe operation region and high breakdown voltage are demanded, and is especially suitable for a high frequency power device used for a power amplifier for which high linearity is required. Since a thin film SOI substrate using a high resistance substrate is used, the present invention is not only suitable for a discrete device, but also for a package where a signal processing circuit and passive element are mounted on a same chip.

The invention has been described with respect to certain preferred embodiments thereof. It will be understood that modifications and variations are possible within the scope of the appended claims.

What is claimed is:

1. A semiconductor device, comprising:
a first conductive type high resistivity region;
a buried oxide region which is formed on a part of a surface layer of the high resistivity region;
a first conductive type first semiconductor region of which resistivity is lower than the high resistivity region, and which is formed on a part of the surface layer of the high resistivity region, so as to contact a side face and a part of a surface of the buried oxide region;
a gate electrode which is formed on a surface of the first semiconductor region via a gate insulation film;
a spacer region which is formed on a side face the gate electrode;
a second conductive type low resistivity drain region which is formed on a part of the surface of the buried oxide region so as to be isolated from the first semiconductor region and the high resistivity region, and aligned with the edge of the spacer region;
a second conductive type second semiconductor region which is formed on a part of the surface of the buried oxide region, so as to be isolated from the high resistivity region, contact the first semiconductor region and the low resistivity drain region, and aligned with the edge of the gate electrode at the low resistivity drain region side;
a first conductive type first low resistivity region which is formed on a part of the surface layer of the high resistivity region so as to be isolated from the first semiconductor region;
a second conductive type low resistivity source region which is formed on a part of the surface layer of the high resistivity region so as to contact the first semiconductor region and the first low resistivity region, and aligned with the edge of the gate electrode at the first low resistivity region side;
a first conductive type second low resistivity region which is formed so as to be aligned with the edge of the spacer region at the first low resistivity region side, and to be thicker than the low resistivity source region;
a first conductive type buried region which is formed so as to be aligned with the edges of the gate electrode at the low resistivity drain region side and at the first low resistivity region side;
a silicide region which is formed on a part of the surface layer of the low resistivity drain region and a part of the surface layer of the low resistivity source region;
an inter-layer insulation film which covers the gate electrode, the spacer region and the silicide region;
a drain electrode which contacts the low resistivity drain region and covers a part of the surface of the inter-layer insulation film; and
a source electrode which contacts the low resistivity source region and covers a part of the surface of the inter-layer insulation film, wherein
the thickness of the low resistivity drain region and the second semiconductor region is in a 150 nm to 300 nm range.

2. The semiconductor device according to claim 1, wherein the buried oxide region is formed of silicon dioxide, and the thickness of the buried oxide region is 400 nm or more.

3. The semiconductor device according to claim 1, wherein the buried oxide region is a SON (Silicon-ON-Nothing) layer, and the thickness of the buried oxide region is 150 nm or more.

4. The semiconductor device according to claim 1, wherein the thickness of the gate insulation film is thicker at the edge side of the gate electrode than at the center side of the gate electrode.

5. A semiconductor device, comprising:
a first conductive type high resistivity region which is formed on a first conductive type low resistivity semiconductor substrate;
a buried oxide region which is formed on a part of a surface layer of the high resistivity region;
a first conductive type first semiconductor region of which resistivity is lower than the high resistivity region, and which is formed on a part of the surface layer of the high resistivity region, so as to contact a side face and a part of a surface of the buried oxide region;
a gate electrode which is formed on a surface of the first semiconductor region via a gate insulation film;
a spacer region which is formed on a side face of the gate electrode;
a second conductive type low resistivity drain region which is formed on a part of the surface of the buried oxide region so as to be isolated from the first semiconductor region and the high resistivity region, and aligned with the edge of the spacer region;
a second conductive type second semiconductor region which is formed on a part of the surface of the buried oxide region so as to be isolated from the high resistivity region, contact the first semiconductor region and the low resistivity drain region, and aligned with the edge of the gate electrode at the low resistivity drain region side;
a first conductive type first low resistivity region which is formed on a part of the surface layer of the high resistivity region so as to be isolated from the first semiconductor region;
a second conductive type low resistivity source region which is formed on a part of the surface layer of the high resistivity region so as to contact the first semiconductor region and the first low resistivity region, and aligned with the edge of the gate electrode at the first low resistivity region side;
a first conductive type second low resistivity region which is formed so as to be aligned with the edge of the spacer region at the first low resistivity region side, and to be thicker than the low resistivity source region;
a first conductive type buried region which is formed so as to be aligned with the edges of the gate electrode at the low resistivity drain region side and at the first low resistivity region side;
a first conductive type third low resistivity region which is formed in a trench which penetrates through the first low resistivity region and the high resistivity region, and reaches the low resistivity semiconductor substrate;
a first conductive type fourth low resistivity region which covers a periphery of the third low resistivity region;
a silicide region which is formed on a part of the surface layer of the low resistivity drain region and a part of the surface layer of the low resistivity source region;
an inter-layer insulation film which covers the gate electrode, the spacer region and the silicide region;
a drain electrode which contacts the low resistivity drain region and covers a part of the surface of the inter-layer insulation film; and
a source electrode which contacts the low resistivity source region and covers a part of the surface of the inter-layer insulation film, wherein
the thickness of the low resistivity drain region and the second semiconductor region is in a 150 nm to 300 nm range.

6. The semiconductor device according to claim 5, wherein the buried oxide region is formed of silicon dioxide, and the thickness of the buried oxide region is 400 nm or more.

7. The semiconductor device according to claim 5, wherein the buried oxide region is a SON (Silicon-ON-Nothing) layer, and the thickness of the buried oxide region is 150 nm or more.

8. The semiconductor device according to claim 5, wherein the thickness of the gate insulation film is thicker at the edge side of the gate electrode than at the center side of the gate electrode.

9. A semiconductor device, comprising:
a first conductive type high resistivity region which is formed on a first conductive type low resistivity semiconductor substrate;
a buried oxide region which is formed on a part of a surface layer of the high resistivity region;
a first conductive type first semiconductor region of which resistivity is lower than the high resistivity region, and which is formed on a part of the surface layer of the high resistivity region, so as to contact a side face and a part of a surface of the buried oxide region;
a gate electrode which is formed on a surface of the first semiconductor region via a gate insulation film;
a spacer region which is formed on a side face of the gate electrode;
a second conductive type low resistivity drain region which is formed on a part of the surface of the buried oxide region, so as to be isolated from the first semiconductor region and the high resistivity region, and aligned with the edge of the spacer region;
a second conductive type second semiconductor region which is formed on a part of the surface of the buried oxide region, so as to be isolated from the high resistivity region, contact the first semiconductor region and the low resistivity drain region, and aligned with the edge of the gate electrode at the low resistivity drain region side;
a first conductive type first low resistivity region which is formed so as to be isolated from the first semiconductor region, and penetrate through the high resistivity region and reach the low resistivity semiconductor substrate;
a second conductive type low resistivity source region which is formed on a part of the surface layer of the high resistivity region, so as to contact the first semiconductor region and the first low resistivity region, and aligned with the edge of the gate electrode at the first low resistivity region side;
a first conductive type second low resistivity region which is formed so as to be aligned with the edge of the spacer region at the first low resistivity region side, and to be thicker than the low resistivity source region;
a first conductive type buried region which is formed so as to be aligned with the edges of the gate electrode at the low resistivity drain region side and at the first low resistivity region side;
a silicide region which is formed on a part of the surface layer of the low resistivity drain region and a part of the surface layer of the low resistivity source region;
an inter-layer insulation film which covers the gate electrode, the spacer region and the silicide region;
a drain electrode which contacts the low resistivity drain region and covers a part of the surface of the inter-layer insulation film; and
a source electrode which contacts the low resistivity source region and covers a part of the surface of the inter-layer insulation film, wherein
the thickness of the low resistivity drain region and the second semiconductor region is in a 150 nm to 300 nm range.

10. The semiconductor device according to claim 9, wherein the buried oxide region is formed of silicon dioxide, and the thickness of the buried oxide region is 400 nm or more.

11. The semiconductor device according to claim 9, wherein the buried oxide region is a SON (Silicon-ON-Nothing) layer, and the thickness of the buried oxide region is 150 nm or more.

12. The semiconductor device according to claim 9, wherein the thickness of the gate insulation film is thicker at the edge side of the gate electrode than at the center side of the gate electrode.

13. A semiconductor device, comprising:
a first conductive type high resistivity region;
a buried oxide region which is formed on a part of a surface layer of the high resistivity region;
a first conductive type first semiconductor region of which resistivity is lower than the high resistivity region, and which is formed on a part of the surface layer of the high resistivity region, so as to contact a side face and a part of a surface of the buried oxide region;
a gate electrode which is formed on a surface of the first semiconductor region via a gate insulation film;
a second conductive type low resistivity drain region which is formed on a part of the surface of the buried oxide region, so as to be isolated from the first semiconductor region and the high resistivity region;
a second conductive type second semiconductor region which is formed on a part of the surface of the buried oxide region, so as to be isolated from the high resistivity region and contact the first semiconductor region and the low resistivity drain region;
a first conductive type first low resistivity region which is formed on a part of the surface layer of the high resistivity region, so as to be isolated from the first semiconductor region;
a second conductive type low resistivity source region which is formed on a part of the surface layer of the high resistivity region, so as to contact the first semiconductor region and the first low resistivity region;
a first conductive type second low resistivity region which is formed so as to be aligned with the edge of a spacer region at the first low resistivity region side, and to be thicker than the low resistivity source region;
an inter-layer insulation film which covers the gate electrode;
a drain electrode which contacts the low resistivity drain region and covers a part of the surface of the inter-layer insulation film; and
a source electrode which contacts the low resistivity source region and covers a part of the surface of the inter-layer insulation film, wherein
the buried oxide region extends to a position overlapping the gate electrode.

14. The semiconductor device according to claim 13, wherein the buried oxide region is formed of silicon dioxide, and the thickness of the buried oxide region is 400 nm or more.

15. The semiconductor device according to claim 13, wherein the buried oxide region is a SON (Silicon-ON-Nothing) layer, and the thickness of the buried oxide region is 150 nm or more.

16. The semiconductor device according to claim 13, wherein the thickness of the gate insulation film is thicker at the edge side of the gate electrode than at the center side of the gate electrode.

17. A fabrication method for a semiconductor device comprising:
forming, via a gate insulation film, a gate electrode on the surface of a high resistivity semiconductor substrate a part of which is formed with a buried oxide film;
covering the surface of a gate electrode at a buried oxide region side and the surface of the high resistivity semiconductor substrate at the buried oxide region side with photo resist;
forming a first semiconductor region by implanting first conductive type ions into the surface layer of the high resistivity semiconductor substrate;
removing the photo resist from the high resistivity semiconductor substrate on which the first semiconductor region is formed;
forming a low resistivity drain region by implanting second conductive type ions into the surface layer of the high resistivity semiconductor substrate;
forming a spacer region on the side face of the gate electrode on the surface of the high resistivity semiconductor substrate on which the low resistivity region is formed; and
forming a second semiconductor region by implanting second conductive type ions into the surface layer of the high resistivity semiconductor substrate on which the spacer region is formed.

18. A fabrication method for a semiconductor device comprising:
forming, via a gate insulation film, a pseudo-gate electrode on a surface of a high resistivity semiconductor substrate a part of which is formed with a buried oxide film;
covering a surface of the pseudo-gate electrode at a buried oxide region side and a surface of the high resistivity semiconductor substrate at the buried oxide region side with photo resist;
forming a first semiconductor region by implanting first conductive type ions into the surface layer of the high resistivity semiconductor substrate;
removing the photo resist from the high resistivity semiconductor substrate on which the first semiconductor region is formed;
forming a low resistivity drain region by implanting second conductive type ions into the surface layer of the high resistivity semiconductor substrate;
forming a spacer region on the side face of the pseudo-gate electrode on the surface of the high resistivity semiconductor substrate on which the low resistivity region is formed;
forming a second semiconductor region by implanting second conductive type ions into the surface layer of the high resistivity semiconductor substrate on which the spacer region is formed; and
forming a gate electrode after removing the pseudo-gate electrode.

19. A fabrication method for a semiconductor device comprising:
forming a device structure on a high resistivity semiconductor substrate a part of which is formed with a buried oxide region formed of silicon dioxide; and
forming a SON layer by removing the silicon dioxide by etching.
